(19) United States
(12) Patent Application Publication
(10) Pub. No.: US 2018/0199452 A1
(43) Pub. Date: Jul. 12, 2018

(54) FLOOR BOX STANDS AND ELECTRICAL BOX ASSEMBLIES

(71) Applicant: Hubbell Incorporated, Shelton, CT (US)

(72) Inventors: Emircan Matthew Dumani, Shelton, CT (US); Sorin Ioan Mortun, Irvington, NY (US)

(21) Appl. No.: 15/860,931

(22) Filed: Jan. 3, 2018

Related U.S. Application Data
(60) Provisional application No. 62/445,629, filed on Jan. 12, 2017.

(51) Int. Cl. H05K 5/02; H02G 3/10

(52) U.S. Cl. CPC H05K 5/0204; H02G 3/105

(57) ABSTRACT

The present disclosure also provides descriptions of electrical box-stands. The present disclosure also provides descriptions of electrical box assemblies that include an electrical box that can be mounted to an electrical box-stand. The electrical box-stands and electrical box assemblies are configured to be embedded within concrete. The electrical box-stand includes one or more adjustable legs. The length of each leg can be adjusted to position the box-stand at a selected distance from a sub-floor.

### CROSS REFERENCE TO RELATED APPLICATIONS

The present disclosure is based on and claims benefit from co-pending U.S. Provisional Application Ser. No. 62/445,629 filed Jan. 13, 2017 entitled “Floor Box Stands and Electrical Box Assemblies” the entire contents of which are incorporated herein by reference.

### BACKGROUND

### Field

The present disclosure relates generally to floor box stands for supporting electrical floor boxes and to electrical floor box assemblies that include an electrical floor box and a floor box stand. More particularly the present disclosure relates to floor box stands and electrical floor box assemblies configured to be embedded within concrete.

### Description of the Related Art

Many types of electrical boxes have been installed in concrete slabs or flooring. In general, electrical boxes together with conduits connected to the electrical boxes are oriented in forms (also referred to as concrete forms) prior to pouring concrete into the form. Once all the electrical boxes are installed in the form and the electrical conduit is connected to the boxes, concrete can be poured onto the form embedding the electrical boxes and electrical conduit in the concrete.

Generally, when installing electrical boxes in forms, it is desirable to have the top of the electrical box, i.e., the open end of the electrical box, within a certain distance to a planned top of the concrete slab or flooring, such as having the top of the electrical box flush with the top surface of the final concrete flooring. To position the electrical boxes in forms at desired locations and at desired heights, the electrical boxes are supported by tying the electrical boxes to one or more reinforcing bars, also known as rebar, or other elements or structures within the form prior to pouring the concrete.

However, in many forms the rebar or other elements or structures may not be in the location where electrical boxes are to be located. Further, even if there is rebar or other elements or structures in proximity to the location where an electrical box is to be located, the height of the rebar or other elements or structures may not accommodate the desired height of the electrical box.

### SUMMARY

The present disclosure provides descriptions of embodiments for adjustable box stands, e.g., floor box stands, configured to be embedded within concrete that support and maintain electrical floor boxes in predetermined locations while concrete is being poured. The present disclosure also provides descriptions of embodiments for adjustable box assemblies, e.g., electrical floor box assemblies, configured to be embedded within concrete.

In one exemplary embodiment, an adjustable box stand includes a base and at least one leg. The base has a body and at least one leg support member extending from the body. The at least one leg has a leg base and a stem. The stem of the at least one leg is adjustable relative to the at least one leg support member. For example, in an exemplary embodiment the at least one leg support member has an elongated threaded aperture, the stem of the at least one leg has a threaded stem, and the stem of the at least one leg is adjusted relative to the at least one leg support member by threading the stem into or out of the threaded aperture in the at least one leg support member. The stem of the at least one leg may include a plurality of markings used to set a height of the body relative to a sub-floor, deck or grade.

In one exemplary embodiment, an adjustable box assembly includes an electrical box and an adjustable box stand. The adjustable box stand includes a base and at least one leg. The base has a body and at least one leg support member extending from the body. The at least one leg has a leg base and a stem. The stem of the at least one leg is adjustable relative to the at least one leg support member. For example, in an exemplary embodiment the at least one leg support member has an elongated threaded aperture, the stem of the at least one leg has a threaded stem, and the stem of the at least one leg is adjusted relative to the at least one leg support member by threading the stem into or out of the threaded aperture in the at least one leg support member. The stem of the at least one leg may include a plurality of markings used to set a height of the body relative to a sub-floor, deck or grade.

### BRIEF DESCRIPTION OF THE DRAWINGS

The figures depict embodiments for purposes of illustration only. One skilled in the art will readily recognize from the following description that alternative embodiments of the structures illustrated herein may be employed without departing from the principles described herein, wherein:

FIG. 1 is a top perspective view of an exemplary embodiment of an electrical box assembly according to present disclosure, illustrating an electrical box attached to a box-stand;

FIG. 2 is a top perspective view of the electrical box of FIG. 1;

FIG. 3 is a bottom plan view of the electrical box of FIG. 2;

FIG. 4 is a top perspective view of the box-stand of FIG. 1;

FIG. 5 is a top perspective view with parts separated of another exemplary embodiment of an electrical box assembly according to the present disclosure, illustrating an electrical box and a box-stand;

FIG. 6 is a top perspective view of the box assembly of FIG. 5 illustrating the electrical box attached to the electrical box-stand;

FIG. 7 is a partial cross-sectional view of the box-stand of FIG. 5 taken along line 7-7;

FIG. 8 is a top perspective view with parts separated of another exemplary embodiment of an electrical box-stand according to the present disclosure, illustrating two box stand members;

FIG. 9 is a top perspective view of a box-stand member of the box-stand of FIG. 8;

FIG. 10 is a top perspective view of the box-stand of FIG. 8, illustrating an upper box-stand member coupled to a lower box-stand member with the box-stand adjusted to a maximum height setting;

FIG. 11 is a top perspective view of another exemplary embodiment of an electrical box assembly according to the present disclosure, illustrating an electrical box attached to a box-stand with the box-stand adjusted to a maximum height setting;

FIG. 12 is a top perspective view of a box-stand member of the box-stand of FIG. 11;

FIG. 13 is a top perspective view of the box-stand of FIG. 11 with the box-stand adjusted to a minimum height setting;

FIG. 14 is a top perspective view of another exemplary embodiment of a box-stand similar to the box-stand of FIG. 11, and illustrating an upper box-stand member coupled to a lower box-stand member in a maximum height setting;

FIG. 15 is a top perspective view of a box-stand member of the box-stand of FIG. 14;

FIG. 16 is a top perspective view of the coupling joint between the upper box-stand member and the lower box-stand member of FIG. 14;

FIG. 17 is a cross-sectional view of the coupling joint of FIG. 16;

FIG. 18 is a bottom perspective view of another exemplary embodiment of a box-stand according to the present disclosure, illustrating a base and a plurality of legs;

FIG. 19 is a top perspective view of a leg of FIG. 18;

FIG. 20 is a top perspective view with parts separated of another exemplary embodiment of an electrical box assembly according to the present disclosure, illustrating an electrical box and a box-stand, where the box-stand legs are adjusted to a maximum height setting;

FIG. 21 is an enlarged view of a leg of the box-stand of FIG. 20 separated from a leg support member;

FIG. 22 is a top perspective view of a portion of the box-stand of FIG. 20 taken from detail 22 and illustrating a leg interconnected to a leg support member;

FIG. 23 is a top perspective view of the electrical box assembly FIG. 20 positioned within a cement form;

FIG. 24 is a top perspective view of another exemplary embodiment of an box-stand according to the present disclosure, illustrating a base and a plurality of legs extending from the base;

FIG. 25 is a top perspective view with parts separated of the box-stand of FIG. 24, illustrating the base and a plurality of legs separated from the base;

FIG. 26 is a bottom perspective view of the box-stand base of FIG. 24;

FIG. 27 is a top perspective view of a box-stand leg of FIG. 24;

FIG. 28 is a top perspective view with parts separated of another exemplary embodiment of an electrical box assembly according to the present disclosure, illustrating an electrical box and a box-stand having a base coupled to a plurality of legs;

FIG. 29 is a top perspective view with parts separated of a portion of the box-stand base of FIG. 28 and a leg;

FIG. 30 is a top perspective view of a portion of the box-stand base of FIG. 28 coupled to two legs and a stabilizing member attached to the two legs;

FIG. 31 is a top perspective view with parts separated of another exemplary embodiment of an electrical box assembly according to the present disclosure, illustrating two embodiments for coupling a box-stand base to a plurality of legs;

FIG. 32 is a top perspective view with parts separated of a portion of the box-stand of FIG. 31 taken from detail 32, and illustrating one embodiment for coupling a box-stand base to a leg;

FIG. 33 is a top perspective view with parts separated of a portion of the box-stand of FIG. 31 taken from detail 33, and illustrating another embodiment for coupling an electrical box-stand base to a leg;

FIG. 34 is a cross-sectional view of the box-stand base of FIG. 31 taken from detail 34;

FIG. 35 is a top perspective view of another exemplary embodiment of an electrical box assembly according to the present disclosure, illustrating box mounting brackets secured to the electrical box and each box mounting bracket coupled to a leg;

FIG. 36 is an enlarged perspective view with parts separated of a portion of a box mounting bracket coupled to a leg taken from detail 36 in FIG. 35;

FIG. 37 is a top perspective view with parts separated of another exemplary embodiment of an electrical box assembly according to the present disclosure, illustrating mounting brackets extending from a base and legs coupled to the mounting brackets;

FIG. 38 is an enlarged perspective view with parts separated of the box mounting bracket coupled to an adjustable leg taken from detail 38 in FIG. 37;

FIG. 39 is a top perspective view with parts separated of another exemplary embodiment of an electrical box assembly according to the present disclosure, illustrating a box-stand having a base attached to legs with adjustment ledges;

FIG. 40 is a top perspective view with parts separated of the box-stand of FIG. 39;

FIG. 41 is an enlarged perspective view with parts separated of the box-stand base coupled to a ledge of a leg taken from detail 41 in FIG. 39;

FIG. 42 is a partial cross-sectional view of the box-stand base of FIG. 39 taken from line 42-42;

FIG. 43 is a top perspective view with parts separated of another exemplary embodiment of a box-stand according to the present disclosure, illustrating a base and a plurality of legs;

FIG. 44 is a side elevation view of leg of the box stand of FIG. 43;

FIG. 45 is a top perspective view of a portion of the leg of FIG. 43 positioned within the base;

FIG. 46 is a top perspective view of a portion of the leg of FIG. 43 positioned within the base and the leg rotated to couple the leg to the base;

FIG. 47 is a top perspective view with parts separated of another exemplary embodiment of a box-stand according to the present disclosure, illustrating a base and a plurality of legs;

FIG. 48 is a top perspective view with parts separated of another exemplary embodiment of an electrical box assembly similar to the box assembly of FIG. 39, and illustrating an electrical box-stand base having one or more box mounting arms;

FIG. 49 is a top perspective view with parts separated of another exemplary embodiment of an electrical box assembly according to the present disclosure, and illustrating a unitary box stand having a base and a plurality of legs extending from the base, each leg having breakaways to adjust the height setting of the box-stand;

FIG. 50 is a top perspective view of a portion of the electrical box-stand base of FIG. 44 coupled to the electrical box using tie wraps, and a portion of a leg breakaway cut off to adjust the height setting of the box stand;

FIG. 51 is a top perspective view of another exemplary embodiment of an electrical box assembly according to the present disclosure, illustrating the electrical box attached to mounting brackets coupled to legs with a plurality of breakaways;

FIG. 52 is an enlarged perspective view with parts separated of an electrical box-stand mounting bracket of FIG. 51 coupled to a leg with a breakaway separated from the bracket;

FIG. 53 is a top perspective view with parts separated of another exemplary embodiment of an electrical box assembly according to the present disclosure, illustrating a unitary box stand having a base and a plurality of legs with a plurality of breakaways extending from the base;

FIG. 54 is a top perspective view of a portion of the box-stand base of FIG. 53 with a portion of a leg breakaway cut off to adjust the height setting of the box-stand;

FIG. 55 is a bottom perspective view of a portion of a leg of FIG. 53;

FIG. 56 is a top perspective view with parts separated of another exemplary embodiment of an electrical box assembly according to the present disclosure, illustrating stackable box-stand plates that form the box-stand;

FIG. 57 is a bottom perspective view of a stackable box-stand plate of FIG. 56;

FIG. 58 is a top perspective view with parts separated of another exemplary embodiment of the stackable box-stand plates of FIG. 56;

FIG. 59 is a top perspective view of another exemplary embodiment of an electrical box assembly according to the present disclosure, illustrating stackable electrical box-stand rings that form the box-stand;

FIG. 60 is a top perspective view of the electrical box-stand of FIG. 59, illustrating the removal of two box-stand rings to adjust the height setting of the box-stand;

FIG. 61 is a top perspective view of another exemplary embodiment of an electrical box assembly according to the present disclosure, illustrating a foldable box-stand having a foldable base and a foldable body;

FIG. 62 is a top perspective view with parts separated of the electrical box assembly of FIG. 61;

FIG. 63 is a front plan view of the foldable base of FIG. 61 prior to folding;

FIG. 64 is a front plan view of the foldable body of FIG. 61 prior to folding;

FIG. 65 is a top perspective view with parts separated of another exemplary embodiment of an electrical box assembly according to the present disclosure, illustrating an electrical box and a box-stand having a base and a plurality of legs;

FIG. 66 is a top perspective view of the base of FIG. 65;

FIG. 67 is a bottom perspective view of the base of FIG. 65;

FIG. 68 is a front perspective view of a leg of FIG. 65;

FIG. 69 is a front plan view of the leg of FIG. 68 illustrating height setting indicators on the leg;

FIG. 70 is a side elevation view of the leg of FIG. 68;

FIG. 71 is a top perspective view of the box stand of FIG. 65, illustrating three legs separated from the base;

FIG. 72 is a top perspective view of the box stand of FIG. 65, illustrating three legs threaded into the base and set to a desired height setting;

FIG. 73 is a top perspective view with parts separated of another exemplary embodiment of an electrical box assembly according to the present disclosure, illustrating an electrical box and an box-stand having a base and a plurality of legs;

FIG. 74 is a top perspective view of the base of FIG. 73;

FIG. 75 is a bottom perspective view of the base of FIG. 73;

FIG. 76 is a front perspective view of a leg of FIG. 73;

FIG. 77 is a front plan view of a leg of FIG. 73;

FIG. 78 is a side elevation view of a leg of FIG. 73;

FIG. 79 is a top perspective view of the box stand of FIG. 73 illustrating a leg positioned for insertion into the base;

FIG. 80 is a top perspective view of the box stand of FIG. 79 illustrating the leg positioned in the base;

FIG. 81 is a side elevation view of the box stand of FIG. 80, illustrating a sectional view of a portion of the base where the leg connects to the base;

FIG. 82 is a top perspective view with parts separated of another exemplary embodiment of an electrical box assembly according to the present disclosure, illustrating an electrical box and a box-stand;

FIG. 83 a top perspective view of the box-stand base of FIG. 82;

FIG. 84 is a bottom perspective view of the box-stand base of FIG. 83;

FIG. 85 is an enlarged view of a leg support member of the box-stand base of FIG. 83 taken from detail 85;

FIG. 86 is a top perspective view of a leg of the box-stand base of FIG. 82;

FIG. 87 is a side elevation view of the leg of FIG. 86 illustrating height setting indicators on the leg;

FIG. 88 is another side elevation view of the leg of FIG. 86;

FIG. 89 is a top perspective view of the box-stand base of FIG. 82 with the legs separated from the base; and

FIG. 90 is a top perspective view of the box-stand base of FIG. 82 with the legs attached to the base.

### DETAILED DESCRIPTION

The present disclosure provides descriptions of embodiments for electrical box assemblies that include an electrical box that can be mounted to an electrical box-stand. The present disclosure also provides descriptions of embodiments of electrical box stands. For ease of description, the electrical box assembly may also be referred to herein as the “box assembly,” the electrical box-stand may also be referred to herein as the “box-stand,” and the electrical box may also be referred to herein as the “box.” This specification and the accompanying drawings are to be regarded in an illustrative sense rather than a restrictive sense. Various modifications may be made thereto without departing from the spirit and scope of the present disclosure.

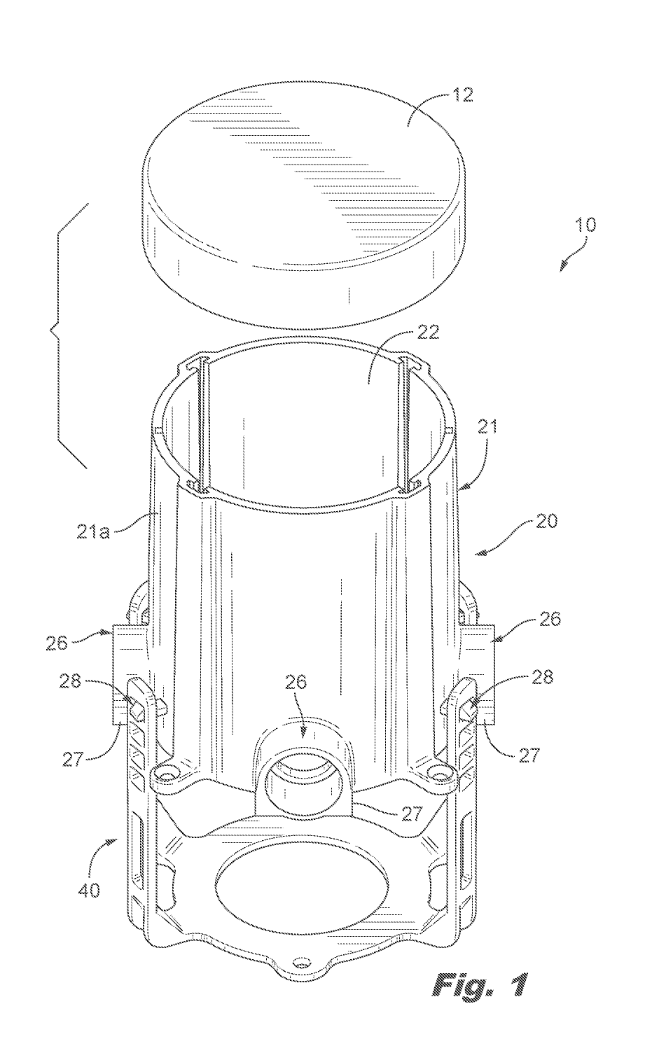

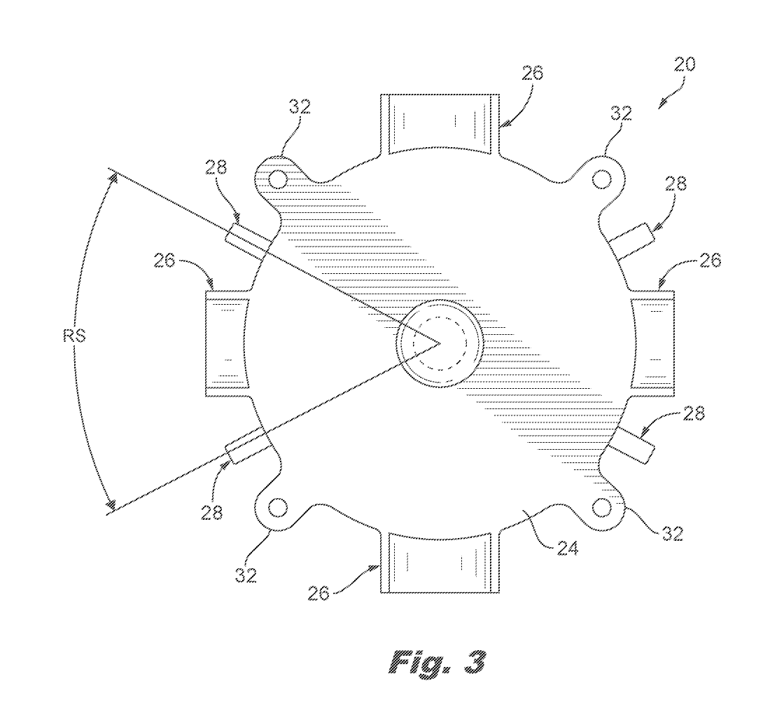

Referring to FIGS. 1-4, an exemplary embodiment of a box assembly according to the present disclosure is shown. In this exemplary embodiment, the box assembly 10 includes a box 20 and box-stand 40. The box assembly 10 may also include a cover 12 that may be inserted over a top opening 22 in the box 20 prior to pouring concrete so that the concrete does not enter the box 20. The box 20 has a housing 21 with the top opening 22 and a closed bottom 24, seen in FIG. 3. The housing 21 may come in a number of shapes. For example, the housing may be a round housing, a square housing, or a rectangular housing. The box 20 shown has a round, non-metallic housing, however, one skilled in the art would readily recognize that the box 20 may have a metallic housing or the box may have a metallic portion and a non-metallic portion, such as a metal housing and a non-metallic riser or extension, as is known. Further, the housing 21 may be divided into compartments, such as high voltage and low voltage compartments as is known.

Adjacent the closed bottom 24 on an outer surface 21a of the housing 21 are one or more conduit hubs 26 each providing an opening into the housing and a connector 27 used to connect electrical conduits to the conduit hub 26 and thus the housing 21. The conduit hubs 26 can come in many sizes, such as ½ inch, ¾ inch, 1 inch, 1½ inch, 2 inches, etc., to connect to various size conduits. The connector 27 of the conduit hub 26 may be configured to receive non-metallic or metallic conduits. When configured to receive non-metallic conduits, the interior of the connector 27 is smooth so that non-metallic conduit can be glued to the conduit hub, using an adhesive, such as PVC glue, as is known in the art. When configured to receive metallic conduits, such as threaded galvanized piping, the interior of the connector portion is threaded so that the metallic conduit can be threaded into the conduit hub 26 as is known in the art. In the exemplary embodiment shown, the conduit hubs 26 are positioned on the housing 21 such that each conduit hub is separated from adjacent conduit hubs by about 90 degrees. The conduit hubs 26 in the embodiment shown are non-metallic conduit hubs integrally formed into the housing 21. However, one skilled in the art would readily recognize that non-metallic knock-outs may be substituted for the conduit hubs to permit conduit connectors to be secured to the housing 21. In instances where the housing 21 is metallic, the metallic housing may have metallic knock-outs to permit metallic or non-metallic conduit connectors to be secured to the housing 21. In instances where the box 20 has a metallic housing and a non-metallic riser, the metallic housing may have metallic knock-outs to permit metallic or non-metallic conduit connectors to be secured to the housing 21.

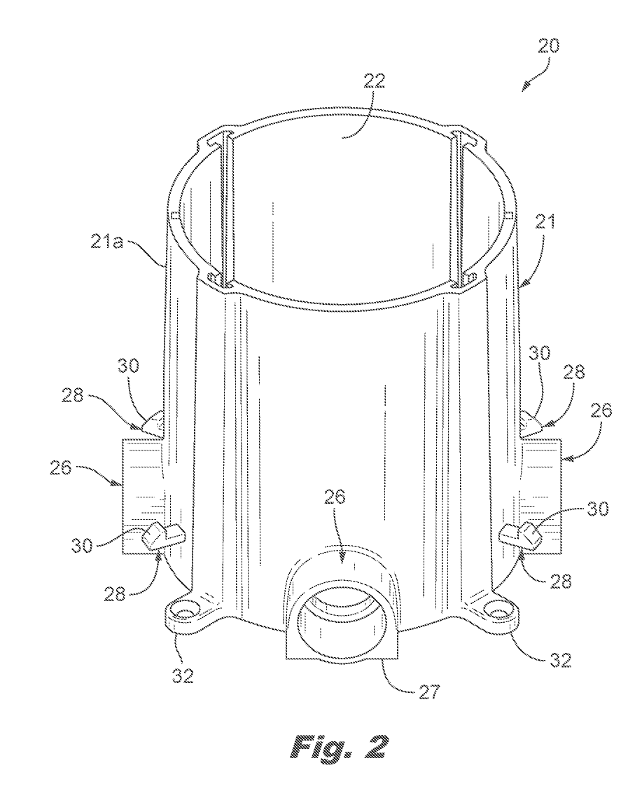

Extending from the outer surface 21a of the housing 21 are one or more box-stand mounting members 28, which in this exemplary embodiment are mounting tabs, seen in FIGS. 2 and 3. Each box-stand mounting member 28 has a proximal end that can be secured to the outer surface 21a of the housing 21, or integrally formed into the housing. Each box-stand mounting member 28 has a distal end extending from the outer surface 21a of the housing. The box-stand mounting members 28 are used to releasably couple the box 20 to the box-stand 40, as will be described below. The distal end of the box-stand mounting member 28 may include a latch member 30 used to latch the box-stand mounting member 28 to the box-stand 40. In the embodiment shown in FIG. 3, there are four box-stand mounting members 28 where two box-stand mounting members are positioned on one side of the housing 21, and the other two box-stand mounting members are positioned on an opposing side of the housing. The two box-stand mounting members 28 on opposing sides of the housing are separated by a radial distance “Rs” which in this exemplary embodiment is about 55 degrees. However, the box-stand mounting members 28 may be positioned in any configuration on the housing sufficient to couple the box 20 to the box-stand 40.

Continuing to refer to FIGS. 1-3, along the outer surface 21a of the housing 21 are one or more mounting rings 32 that may be used to secure the box 20 to, for example, a box-stand, sub-flooring, decking or grade. The mounting rings 32 may be secured to or integrally formed to the housing 21. In the embodiment shown in FIG. 3, the mounting rings 32 are positioned on the housing such that each mounting ring is separated from adjacent mounting rings by about 90 degrees. However, the mounting rings 32 may be positioned in any configuration on the housing sufficient to secure the box 20 to, for example, a box-stand, sub-flooring, decking or grade.

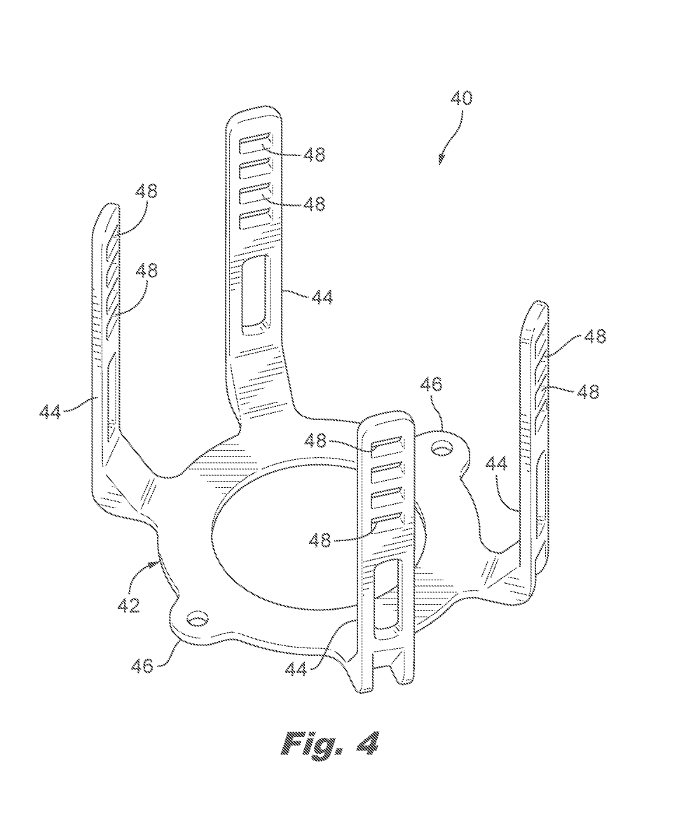

Referring to FIG. 4, the box-stand 40 includes a base 42 and one or more legs 44 extending from the base 42. The one or more legs 44 may be secured to the base 42 or the one or more legs 44 may be integrally formed into the base 42. The base 42 may include one or more mounting rings 46 used to secure the box-stand 40 to, for example, sub-flooring, decking or grade. As an example, fasteners such as nails or screws can be used to secure the box-stand 40 to sub-flooring or decking. As another example, fasteners such as spikes can be sued to secure the box-stand 40 to grade. The box-stand 40 according to the present disclosure is configured to permit adjustment of the height setting of the box 20 relative to a sub-floor, deck or grade. In the exemplary embodiment of FIGS. 1-4, each leg 44 includes a plurality of height adjustment notches 48 configured to receive a box-stand mounting member 28, as shown in FIG. 1. When a box-stand mounting member 28 is inserted into a height adjustment notch 48, the latch member 30 is deflected downwardly until the latch member passes through the notch 48 at which point the latch member springs back to its normal position to releasably latch the box-stand mounting member 28 to the height adjustment notch 48. To release the latch member 30 from the height adjustment notch 48 a downward force is applied to the latch member 30. The box-stand 40 may be made of a non-metallic material, such as injection molded thermoplastic, or the box-stand 40 may be made of a metallic material, such as galvanized steel, stainless steel or aluminum.

Referring to FIGS. 5-7, another exemplary embodiment of a box assembly according to the present disclosure is shown. In this exemplary embodiment, box assembly 60 includes a box 70 and a box-stand 90. The box assembly 60 may also include a cover 62, seen in FIG. 6, that may be inserted over a top opening in the box 70 prior to pouring concrete so that the concrete does not enter the box. The box 70 has a housing 71 with a top opening 72 and a closed bottom 74 similar to the box 20 described above. The housing 71 may come in a number of shapes. For example, the housing may be a round housing, a square housing, or a rectangular housing. The housing 71 shown is a round, non-metallic housing, however, one skilled in the art would readily recognize that the box 70 may have a metallic housing or the box may have a metallic portion and a non-metallic portion, such as a metallic housing and a non-metallic riser or extension. Further, the housing 71 may be divided into compartments, such as high voltage and low voltage compartments.

Adjacent the closed bottom 74 on an outer surface 71a of the housing 71 are one or more conduit hubs 76 each providing an opening into the housing and a connector 77 used to connect electrical conduits to the conduit hub 76 and thus the housing 71. The conduit hubs 76 can come in many sizes, such as ½ inch, ¾ inch, 1 inch, 1½ inch, 2 inches, etc., to connect to various size conduits. In the exemplary embodiment shown, conduit hub 76 pairs are positioned on opposite sides of the housing 71 where each conduit hub pair is separated by about 180 degrees. The conduit hubs 76 in the embodiment shown are non-metallic conduit hubs integrally formed into the housing 71. However, one skilled in the art would readily recognize that non-metallic knock-outs may be substituted for the conduit hubs to permit conduit connectors to be secured to the housing 71. In instances where the box 70 has a metallic housing, the metallic housing may have metallic knock-outs to permit metallic or non-metallic conduit connectors to be secured to the housing 71. In instances where the box 70 has a metallic housing and a non-metallic riser, the metallic housing may have metallic knock-outs to permit metallic or non-metallic conduit connectors to be secured to the housing 71.

Continuing to refer to FIGS. 5-7, along the outer surface 71a of the housing 71 are one or more mounting rings 78. In this embodiment, the mounting rings 78 are used to couple the box 70 to the box-stand 90 as will be described below. The mounting rings 78 may be secured to or integrally formed into the housing 71. In the embodiment shown, the mounting rings 78 may be positioned on the housing such that each mounting ring is separated from adjacent mounting rings by about 90 degrees. However, the mounting rings 78 may be positioned in any configuration sufficient to secure the box 70 to the box-stand 90.

Secured to and extending from the mounting rings 78 are one or more box-stand mounting members 80. Each box-stand mounting member 80 has a proximal end and a free distal end. The proximal end of the box-stand mounting member 80 has a threaded rod 82, seen in FIG. 7, extending therefrom and substantially perpendicular to the box-stand mounting member 80. The threaded rod 82 is used to secure the box-stand mounting member 80 to the housing 71 via mounting rings 78. More specifically, the threaded rod 82 is inserted into an aperture 79 in the mounting ring 78 and a nut 84, seen in FIG. 7, is secured to the threaded rod 82. The distal end of each box-stand mounting member 80 is used to couple the box 70 to the box-stand 90.

Continuing to refer to FIGS. 5-7, the box-stand 90 includes a base 92 and one or more legs 94 extending from the base 92. The one or more legs 94 may be secured to the base 92 or the one or more legs 94 may be integrally formed into the base 92. The base 92 may include one or more mounting rings 96 used to secure the box-stand 90 to sub-flooring, decking or grade. As an example, fasteners such as nails or screws can be used to secure the box-stand 90 to sub-flooring or decking. As another example, fasteners such as spikes can be sued to secure the box-stand 90 to grade. The box-stand 90 according to the present disclosure is configured to permit adjustment of the height of the box 70 relative to a sub-floor, deck or grade. In the exemplary embodiment shown, each leg 94 includes a plurality of height adjustment notches 98 configured to receive a box-stand mounting member 80, as shown in FIGS. 6 and 7. The height setting of the box 70 relative to a subfloor, deck or grade is determined by which notch 98 is used. The box-stand 90 may be made of a non-metallic material, such as injection molded thermoplastic, or the box-stand 90 may be made of a metallic material, such as galvanized steel, stainless steel or aluminum.

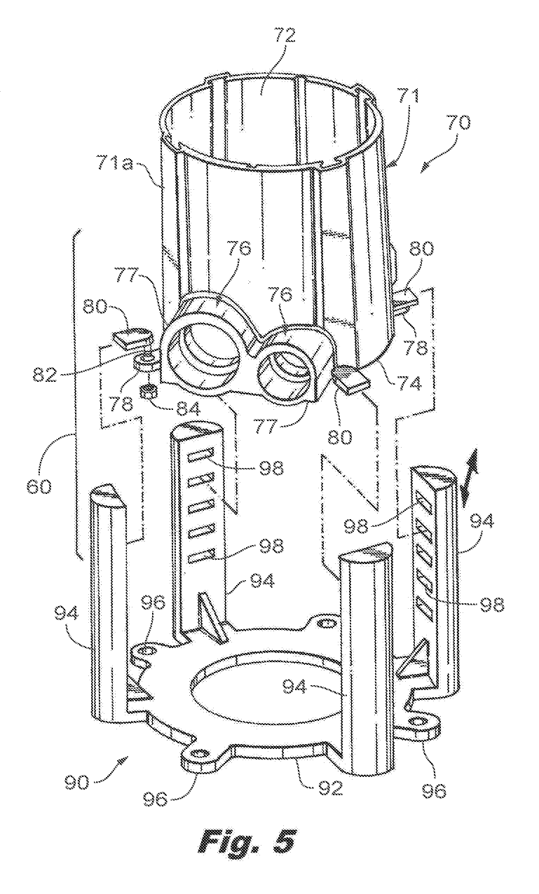

Referring to FIGS. 8-10, another exemplary embodiment of a box-stand 100 that may be used with the box assemblies described herein is shown. In this exemplary embodiment, the box-stand 100 includes a pair of box-stand members 102, where one box-stand member is an upper box-stand member and the other box-stand member is a lower box-stand member. Each box-stand member 102 may be made of a non-metallic material, such as injection molded thermoplastic, or each box-stand member 102 may be made of a metallic material, such as galvanized steel, stainless steel or aluminum. As shown in FIG. 9, each box-stand member 102 includes a base 110 and a plurality of pedestals 112. The pedestals 112 may be secured to the base 110 or integrally formed into the base 110. In the embodiment shown, the pedestals 112 are arranged in sets 114, here sets 114a, 114b and 114c. Each pedestal set 114 includes a plurality of pedestals 112 of different heights “Hx” where “x” is a reference number. A top portion 112a of each pedestal 112 may include an interlocking member 115, which may be a pin 116 with a latch member 118 at a distal end, as shown in FIGS. 8 and 9.

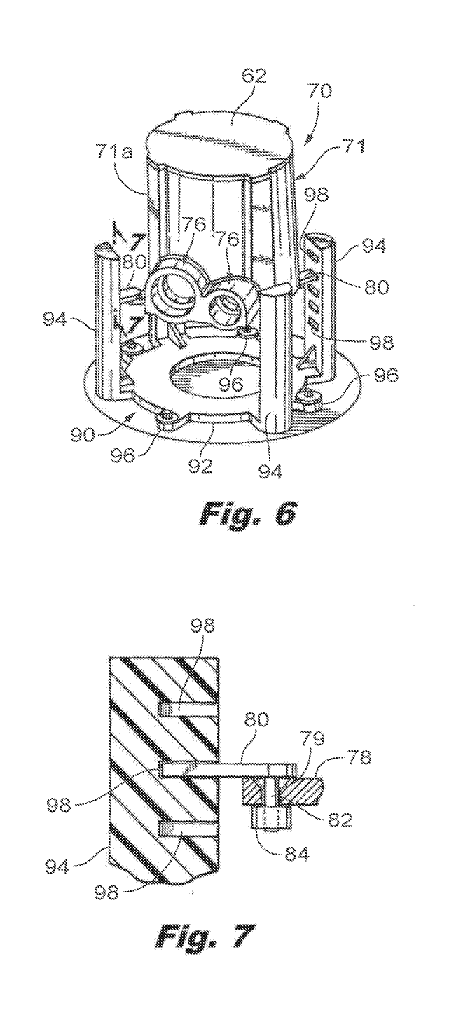

To assemble the box-stand 100, one box-stand member 102 is positioned over another box-stand member 102 so that the top portions 112a of each pedestal on one box-stand member 102 faces a top portion 112a of each pedestal on the other box-stand member 102, as seen in FIG. 8. One of the box-stand members 102 is then rotated relative to the other box-stand member to set the desired height of the box-stand 100, as seen in FIG. 10. When one or more pedestals 112 of one box-stand member are interlocked with one or more pedestals 112 of the other box-stand member, the pin 116 and latch members 118 of each pedestal pass each other with the latch members 118, e.g., hooks, facing each other so that the latch members may catch each other. In this embodiment, if one box-stand member is separated from the other, the latch members 118 will catch preventing complete separation of the box-stand members 102. To separate the box-stand members 102, one box-stand member is rotated relative to the other box-stand member so that the latch members 118 no longer engage each other.

Referring to FIGS. 11-13, another exemplary embodiment of a box assembly according to the present disclosure is shown. In this exemplary embodiment, box assembly 120 includes a box 130 and a box-stand 150. The box assembly 120 may also include a cover 122, seen in FIG. 11, that may be inserted over a top opening in the box 130 prior to pouring concrete so that the concrete does not enter the box. The box 130 may be secured to the box-stand 150 using an adhesive, such as a PVC glue, double sided tape, a hook and loop type fastener, mechanical fasteners, such as sheet metal screws, or other type of fasteners.

The box 130 has a housing 131 with a top opening and a closed bottom similar to the box 20 described above. The housing 131 may come in a number of shapes. For example, the housing may be a round housing, a square housing, or a rectangular housing. The box 130 shown has a round, non-metallic housing, however, one skilled in the art would readily recognize that the box 130 may have a metallic housing, or the box may have a metallic portion and a non-metallic portion, such as a metal housing and a non-metallic riser or extension. Further, the housing 131 may be divided into compartments, such as high voltage and low voltage compartments.

Adjacent the closed bottom on an outer surface 131a of the housing 131 are one or more conduit hubs 132 each providing an opening into the housing and a coupling portion 132a used to connect electrical conduits to the conduit hub 132 and thus the housing 131. The conduit hubs 132 can come in many sizes, such as ½ inch, ¾ inch, 1 inch, 1½ inch, 2 inches, etc., to connect to various size conduits. In the exemplary embodiment shown, there are two conduit hubs 132 positioned on opposite sides of the housing 131 where each conduit hub is separated from the other by about 180 degrees. The conduit hubs 132 in the embodiment shown are non-metallic conduit hubs integrally formed into the housing 131. However, one skilled in the art would readily recognize that non-metallic knock-outs may be substituted for the conduit hubs to permit conduit connectors to be secured to the box 130. In instances where the box 130 has a metallic housing, the metallic housing may have metallic knock-outs to permit metallic or non-metallic conduit connectors to be secured to the housing 131. In instances where the box 130 has a metallic housing and a non-metallic riser, the metallic housing may have metallic knock-outs to permit metallic or non-metallic conduit connectors to be secured to the housing 131.

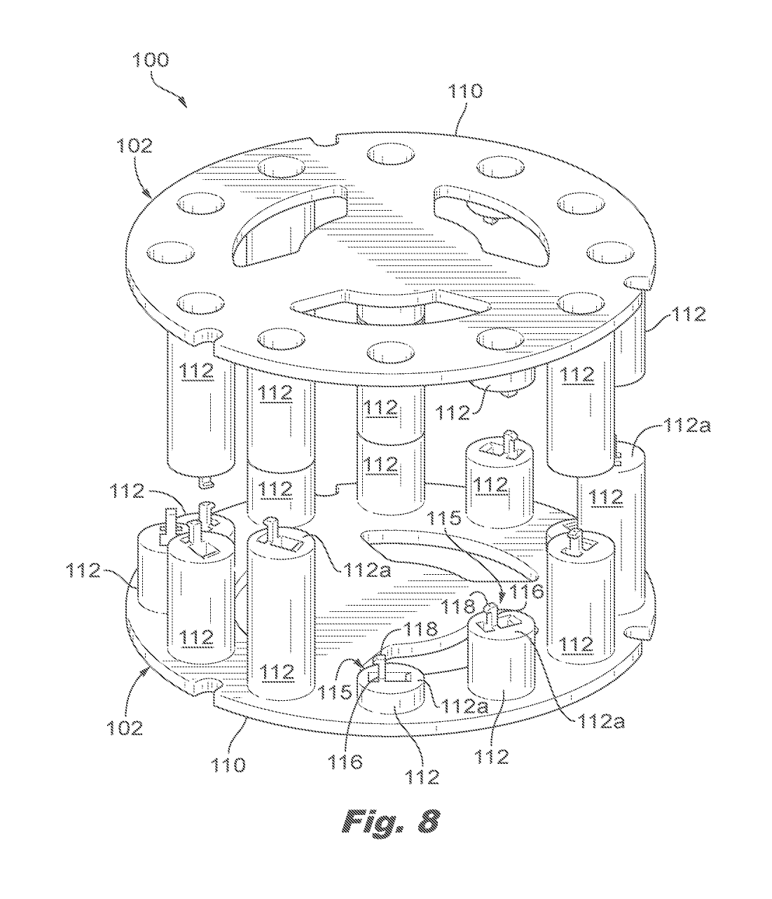

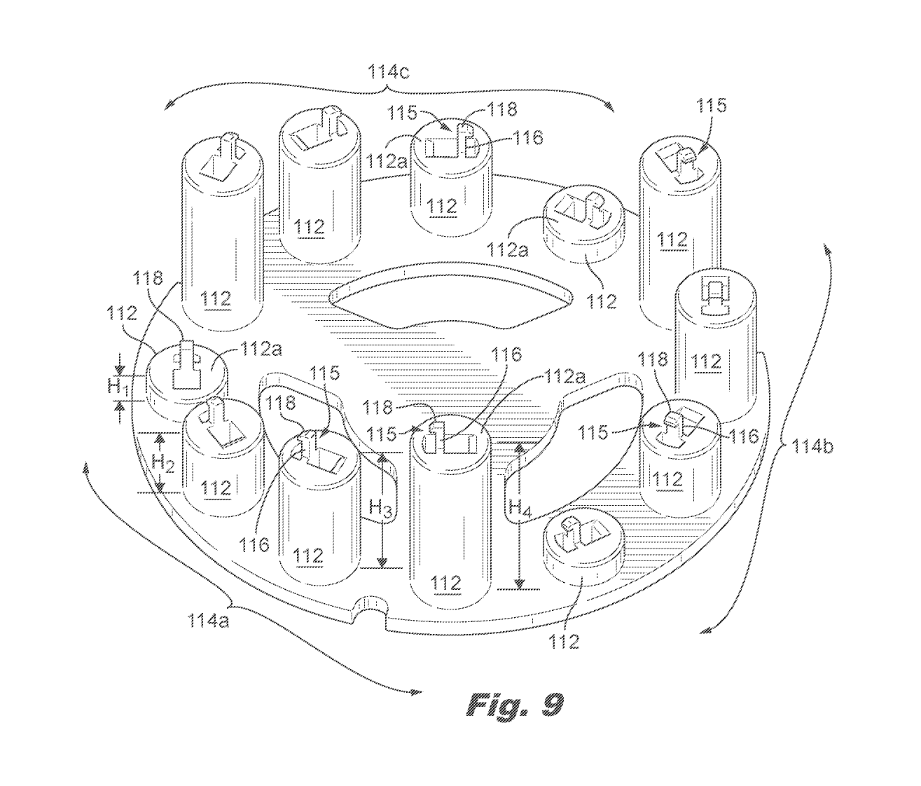

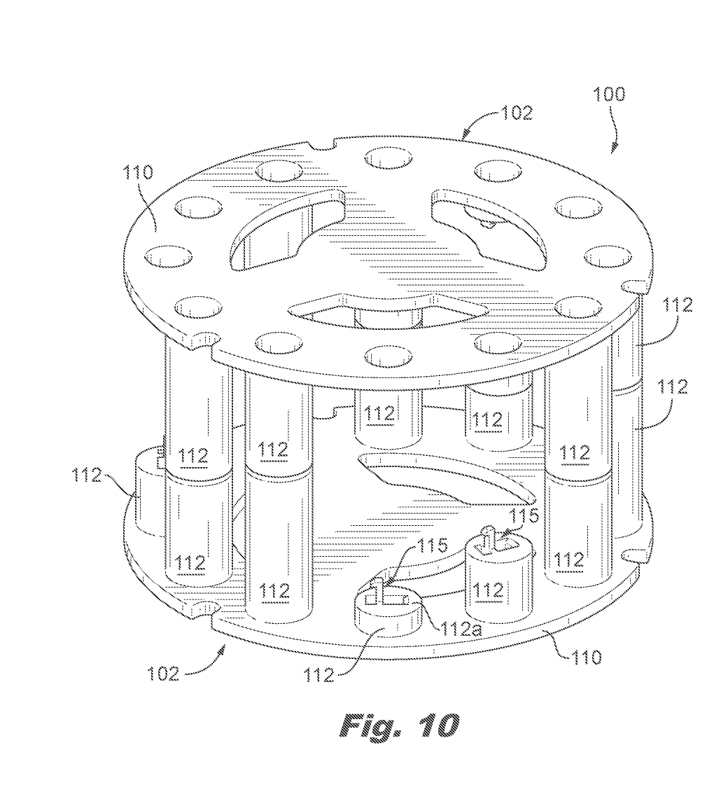

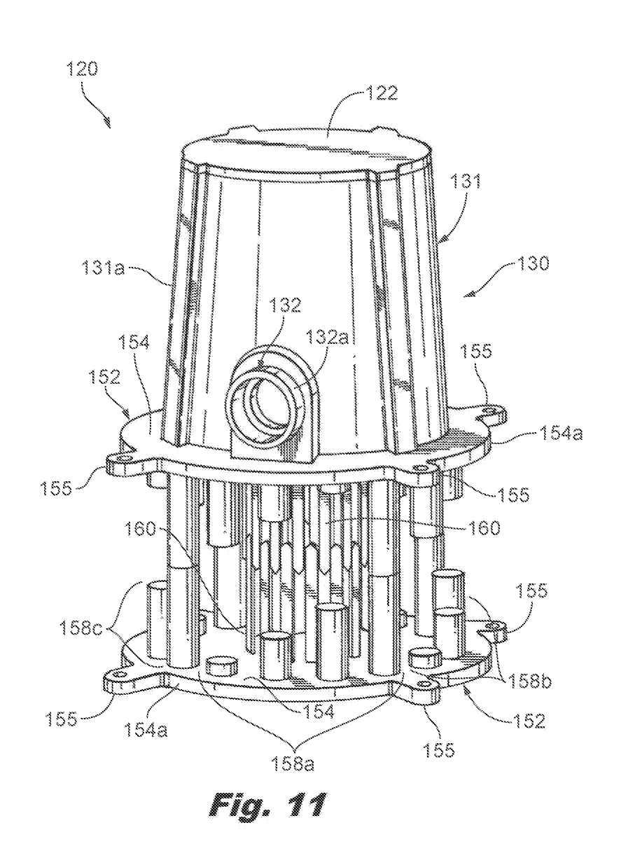

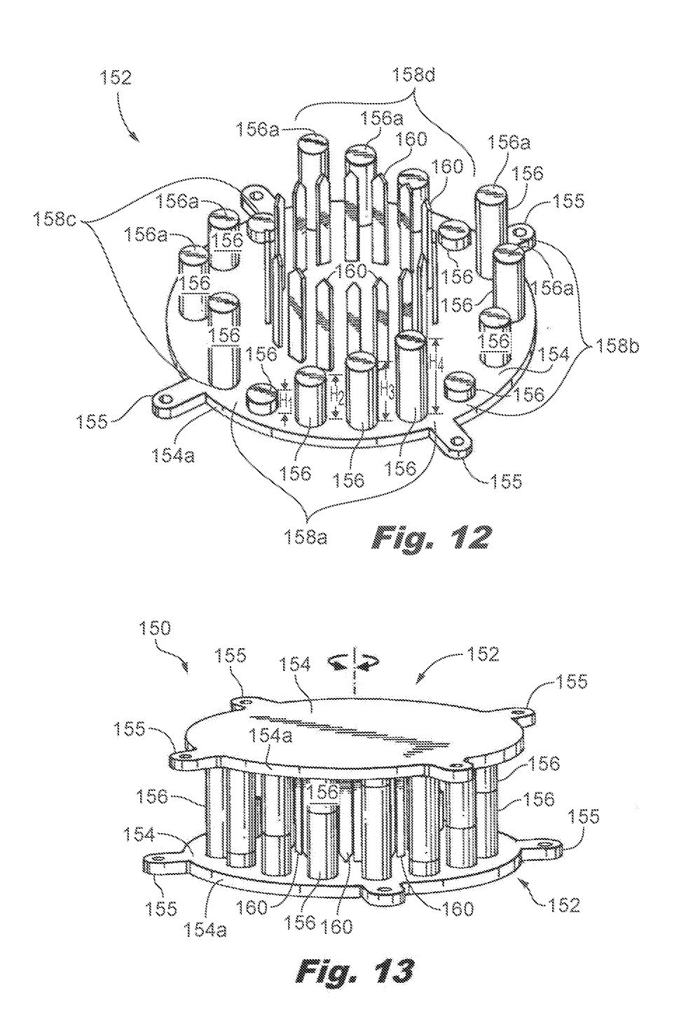

Continuing to refer to FIGS. 11-13, the box-stand 150 includes a pair of box-stand members 152, where one box-stand member is an upper box-stand member and the other box-stand member is a lower box-stand member. Each box-stand member 152 may be made of a non-metallic material, such as injection molded thermoplastic, or each box-stand member 152 may be made of a metallic material, such as galvanized steel, stainless steel or aluminum. As shown in FIG. 12, each box-stand member 152 includes a base 154 and a plurality of pedestals 156. Along an outer surface 154a of the base 154 are one or more mounting rings 155 that may be used to secure the box-stand 150 to, for example, a sub-floor, deck or grade. The mounting rings 155 may be secured to or integrally formed to the base 154. In the embodiment shown in FIG. 12, the mounting rings 155 are positioned on the base such that each mounting ring is separated from adjacent mounting rings by about 90 degrees. However, the mounting rings 155 may be positioned in any configuration sufficient to secure the base 154 to, for example, the sub-floor, deck or grade.

Referring to FIG. 12, the pedestals 156 may be secured to the base 154 or integrally formed into the base 154. In the embodiment shown, the pedestals 156 are arranged in sets 158, here sets 158a, 158b, 158c and 158d. Each pedestal set 158 includes a plurality of pedestals 156 of different heights “Hx” where “x” is a reference number. A top portion 156a of each pedestal 156 is flat so that an opposing top portion of a pedestal can rest on the pedestal, as will be described below. To assemble the box-stand 150, one box-stand member 152 is positioned over another box-stand member 152 so that the top portions 156a of the pedestals 156 on one box-stand member 152 face the top portions 156a of pedestals on the opposing box-stand member. One of the box-stand members 152 is then rotated relative to the other box-stand member to set the desired height of the box-stand 150 and the pedestals are placed on the opposing pedestals. In the embodiment shown in FIG. 11, the height setting of the box-stand is at a maximum height setting. In the embodiment shown in FIG. 13, the height setting of the box-stand is at a minimum height setting. To better maintain the position of the upper box-stand member 152 relative to the lower box-stand member 152, each box-stand member may include a circular array of alignment posts 160. When the upper box-stand member is mated with the lower box-stand member, the alignment posts 160 of one box-stand member slide between the alignment posts 160 of the other box-stand member to limit rotational and lateral movement of the box-stand members 152 relative to each other.

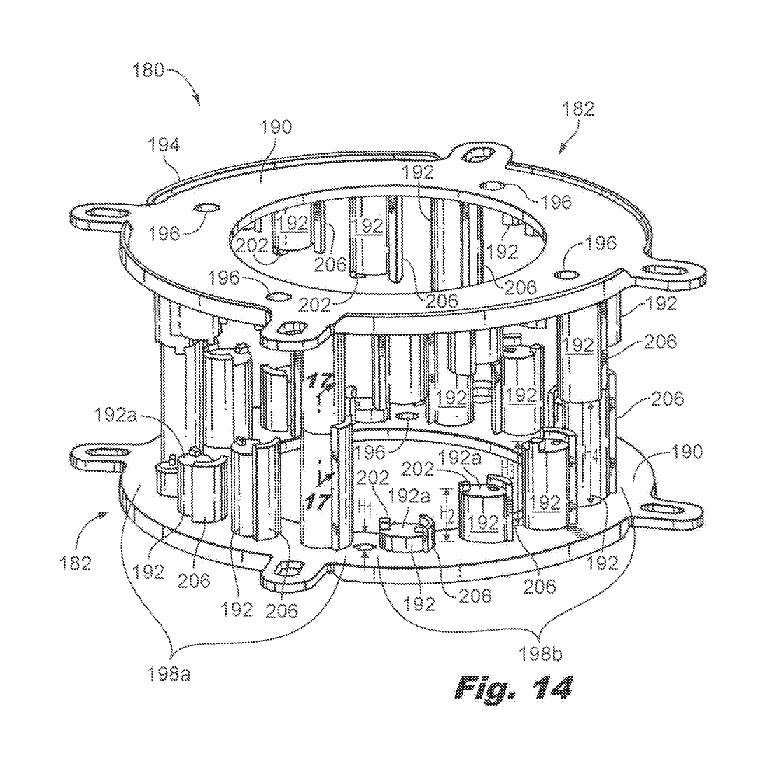

Referring to FIGS. 14-17, another exemplary embodiment of a box-stand that may be used with the box assemblies described herein is shown. In this exemplary embodiment, the box-stand 180 includes a pair of box-stand members 182, where one box-stand member is an upper box-stand member and the other box-stand member is a lower box-stand member. Each box-stand member 182 may be made of a non-metallic material, such as injection molded thermoplastic, or each box-stand member 182 may be made of a metallic material, such as galvanized steel, stainless steel or aluminum.

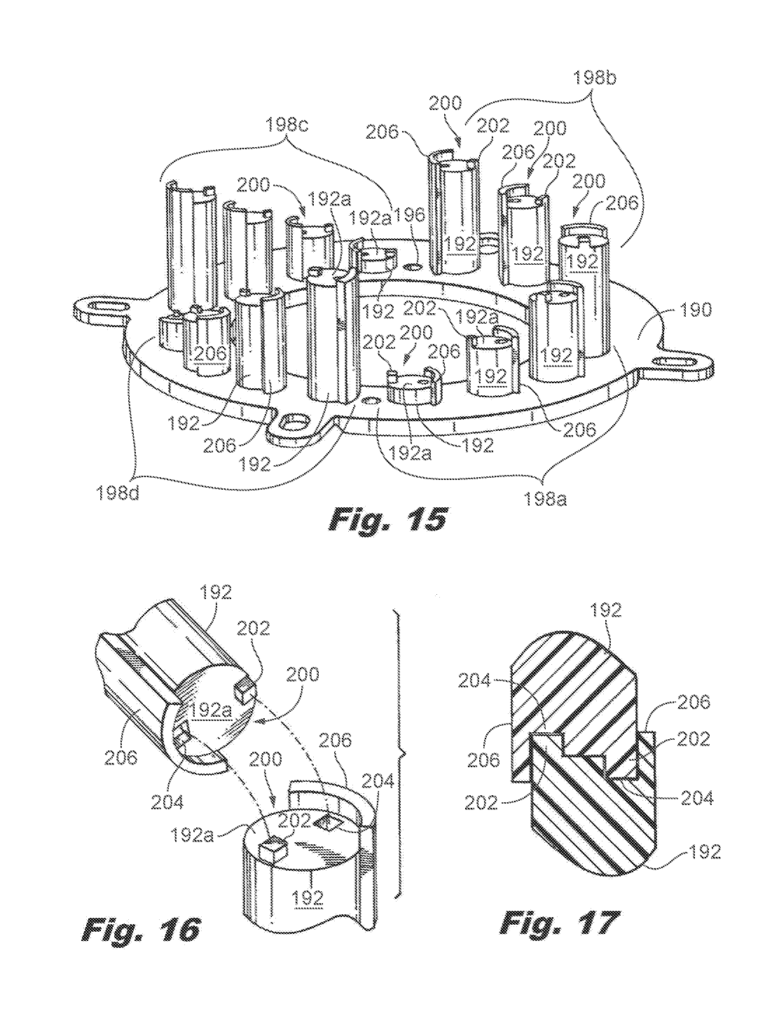

As shown in FIG. 15, each box-stand member 182 includes a base 190 and a plurality of pedestals 192. The base 190 may be in the form of a ring and includes a raised edge 194, seen in FIG. 14, to align a box with the box-stand member 182. The base 190 may also include one or more mounting apertures 196 used to secure a box to the base 190 using, for example, fasteners such as machine screws or nuts and bolts.

The pedestals 192 may be secured to the base 190 or integrally formed into the base 190. In the embodiment shown, the pedestals 192 are arranged in sets 198, here sets 198a, 198b, 198c, and 198d. Each pedestal set 198 includes a plurality of pedestals 192 of different heights “Hx” where “x” is a reference number. A top portion 192a of each pedestal 192 may include an interlocking mechanism 200, which may include pin 202, notch 204, and stop 206, as shown in FIGS. 16 and 17. To assemble the box-stand 180, one box-stand member 182 is positioned over another box-stand member 182, as shown in FIG. 14, so that the top portions 192a of each pedestal 192 on box-stand member 182 faces a top portion 192a of each pedestal on the other box-stand member. One of the box-stand members 192 is then rotated relative to the other box-stand member to set the desired height of the box-stand 180, as seen in FIG. 14. In the embodiment shown in FIG. 14, the height of the box-stand is at a maximum height setting. When one or more pedestals 192 of one box-stand member are interlocked with one or more pedestals 192 of the other box-stand member, the pin 202, notch 204 and stop 206 of each opposing pedestal engage as shown FIGS. 16 and 17.

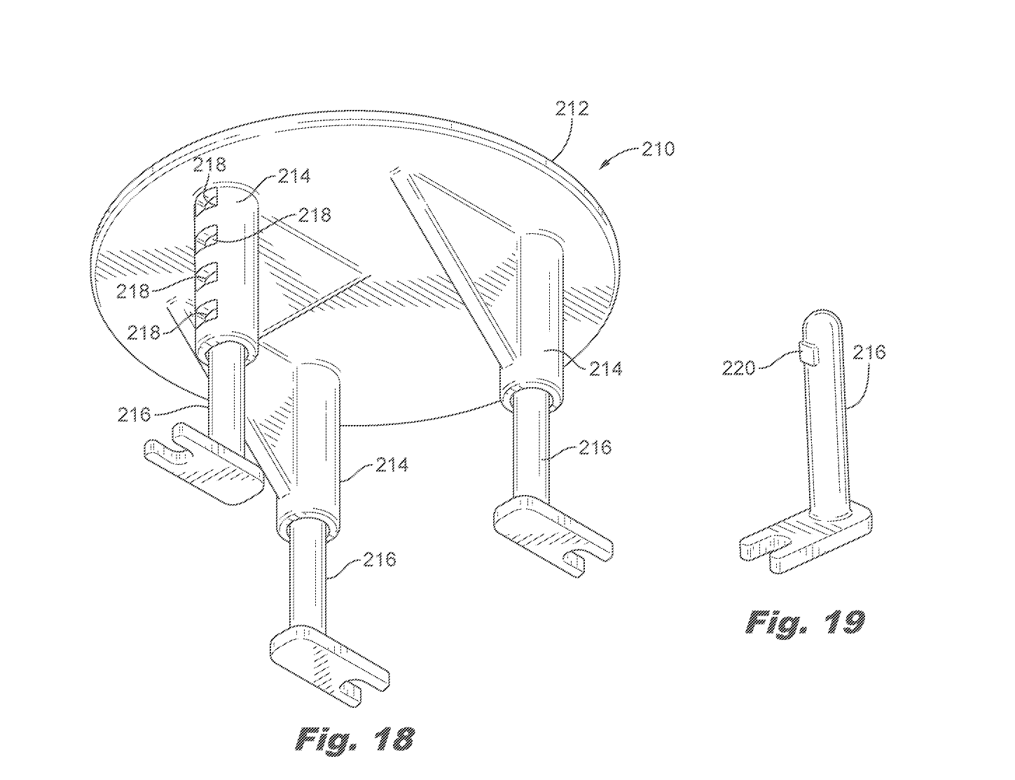

Turning now to FIGS. 18 and 19, another exemplary embodiment of a box-stand 210 that may be used with the box assemblies described herein is shown. In this exemplary embodiment, the box-stand 210 includes a base 212 having one or more leg support members 214, and one or more legs 216 each configured to couple with one of the one or more leg support members 214. The box-stand 210 may be made of a non-metallic material, such as injection molded thermoplastic, or the box-stand 210 may be made of a metallic material, such as galvanized steel, stainless steel or aluminum. In another embodiment, the base 212 and one or more leg support members 214 may be made of a non-metallic material and the one or more legs may be made of a metallic material. In another embodiment, the base 212 and one or more leg support members 214 may be made of a metallic material and the one or more legs may be made of a non-metallic material.

Each leg support member 214 includes an opening for receiving a leg 216 and a plurality of height adjustment notches 218 configured to receive a detent 220 on leg 216. When a leg 216 is inserted into the opening in the of the leg support member 214 to a desired height, the detent 220 rests within a height adjustment notch 218 to releasably secure the leg 216 to the leg support member 214 at the desired height setting. To release the detent 220 from the height adjustment notch 218, the leg 216 is pivoted so that the detent is no longer within height adjustment notch 218 and then the leg 216 can be moved from the opening in the leg support member 214. In the embodiment shown in FIG. 18, the height of the box-stand 210 is at a maximum height setting.

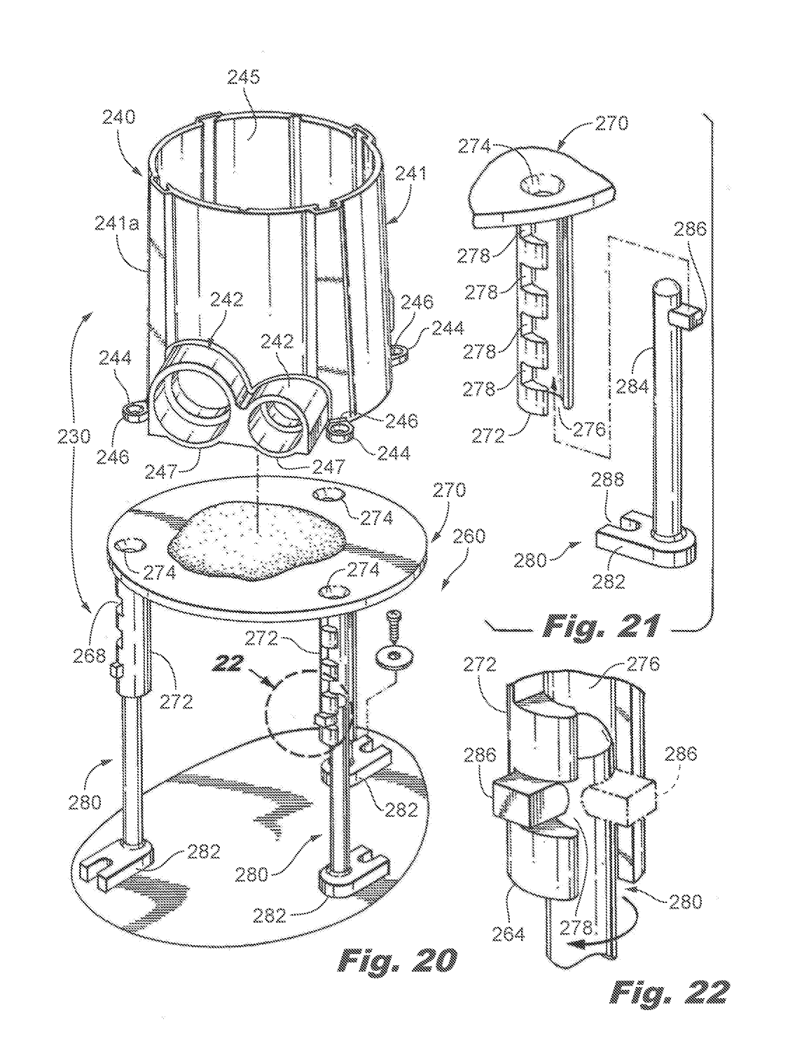

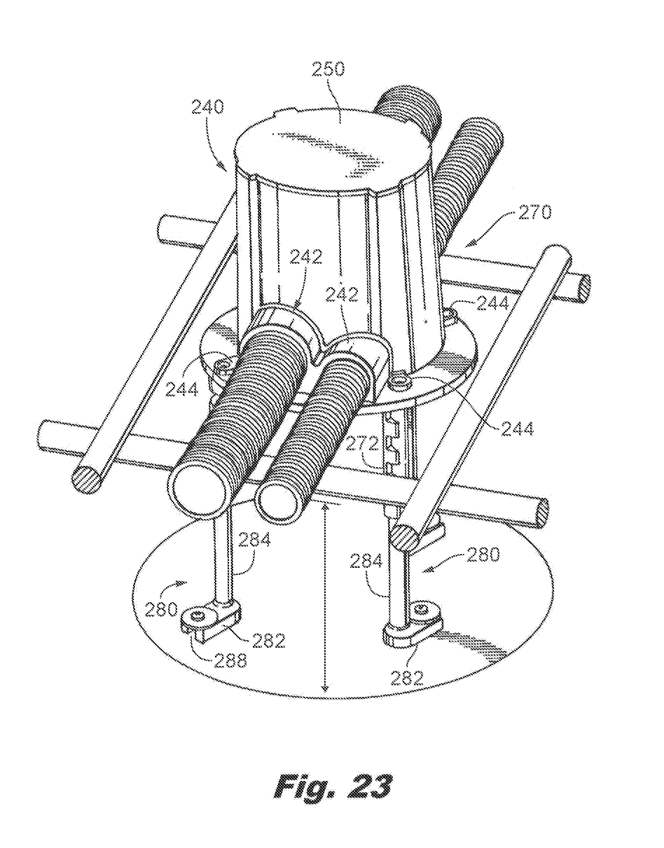

Referring now to FIGS. 20-23, another exemplary embodiment of a box assembly according to the present disclosure is shown. In this exemplary embodiment, box assembly 230 includes a box 240 and a box-stand 260. The box assembly 230 may also include a cover 250, seen in FIG. 23, that may be inserted over a top opening 245 in the box 240 prior to pouring concrete so that the concrete does not enter the box, as described above. The box 240 has housing 241 with the top opening 245 and a closed bottom similar to the box 20 described above. The housing 241 may come in a number of shapes. For example, the housing may be a round housing, a square housing, or a rectangular housing. The box 240 shown has a non-metallic housing, however, one skilled in the art would readily recognize that the box 240 may have a metallic housing or the box may have a metallic portion and a non-metallic portion, such as a metal housing and a non-metallic riser or extension. Further, the housing 241 may be divided into compartments, such as high voltage and low voltage compartments.

Adjacent the closed bottom on an outer surface 241a of the housing 241 are one or more conduit hubs 242 each providing an opening into the housing and a connector 247 used to connect electrical conduits to the conduit hub 242 and thus the housing 241. The conduit hubs 242 can come in many sizes, such as ½ inch, ¾ inch, 1 inch, 1½ inch, 2 inches, etc., to connect to various size conduits. In the exemplary embodiment shown, conduit hub 242 pairs are positioned on opposite sides of the box 240 where each conduit hub pair is separated by about 180 degrees. The conduit hubs 242 in the embodiment shown are non-metallic conduit hubs integrally formed into the housing 241. However, one skilled in the art would readily recognize that non-metallic knock-outs may be substituted for the conduit hubs to permit conduit connectors to be secured to the housing 241. In instances where the box 240 has a metallic housing, the metallic housing may have metallic knock-outs to permit metallic or non-metallic conduit connectors to be secured to the housing 241. In instances where the box 240 has a metallic housing and a non-metallic riser, the metallic housing may have metallic knock-outs to permit metallic or non-metallic conduit connectors to be secured to the housing 241.

Referring to FIG. 20, along the outer surface 241a of the housing 241 are one or more mounting rings 244 each having an aperture 246. The mounting rings 244 may be used to couple the box 240 to the box-stand 260. The mounting rings 244 may be secured to or integrally formed into the housing 241. In the embodiment shown, the mounting rings 244 may be positioned on the housing such that each mounting ring is separated from adjacent mounting rings by about 90 degrees. However, the mounting rings 244 may be positioned in any configuration sufficient to secure the box 240 to the box-stand 260. In an alternative embodiment, the box 240 may be secured to the box stand using, for example adhesives, such as PVC glue, double sided tape, a hook and loop type fastener, mechanical fasteners, such as sheet metal screws, or other type of fasteners.

In this exemplary embodiment, the box-stand 260 includes a base 270 having one or more leg support members 272, and one or more legs 280 each configured to couple with one of the one or more leg support members 272. The box-stand 260 may be made of a non-metallic material, such as injection molded thermoplastic, or the box-stand 260 may be made of a metallic material, such as galvanized steel, stainless steel or aluminum. In another embodiment, the base 270 and one or more leg support members 272 may be made of a non-metallic material, and the one or more legs 280 can be made of a metallic material. In another embodiment, the base 270 and one or more leg support members 272 may be made of a metallic material, and the one or more legs 280 can be made of a non-metallic material.

The base 270 may include one or more mounting apertures 274 used to secure the box 240 to the base 270 using for example fasteners, such as machine screws. To provide additional stability to the leg support members 272, each leg support member may be aligned with the mounting apertures 274 such that when the box 240 is secured to the base 270 using fasteners, e.g., screws, through the mounting apertures 274, the fastener can also enter the leg supporting member 272. As shown in FIG. 21, each leg support member 272 includes a slotted channel 276 for receiving a stem 284 of the leg 280, and a plurality of height adjustment notches 278 configured to receive an arm 286 extending from the stem 284.

As seen in FIGS. 21 and 22, each leg 280 includes a base 282, the stem 284 and the arm 286 described above. The base 282 includes a notch, slot or aperture 288 that can be used to secure the leg 280 to a sub-floor, grade or deck. The leg 280 may be made of a non-metallic material, such as injection molded thermoplastic, or the leg 280 may be made of a metallic material, such as galvanized steel, stainless steel or aluminum.

To secure a leg 280 to the base 270, the stem 284 of the leg 280 is inserted into the slotted channel 276 of the leg support member 272. Generally, a leg is inserted into the slotted channel 276 with the arm 286 aligned with the slotted channel 276 so that the leg can move freely within the slotted channel. When a leg 280 is inserted into the slotted channel 276 in the leg support member 272 and moved to a desired height setting, the stem 284 is then rotated, e.g., rotated counter clockwise, so that the arm 286 rests within a height adjustment notch 278 to releasably secure the leg 280 to the leg support member 272 at the desired height setting. To release the arm 286 from the height adjustment notch 278, the leg 280 is rotated, e.g., is rotated clockwise, so that the arm is no longer within height adjustment notch 278. The leg 280 can be moved within the slotted channel 276 to another height adjustment notch or removed from the slotted channel. As seen in FIG. 23, the box 240 and box-stand 260 are shown in a concrete form between rebar with the box-stand legs 280 secured to a sub-floor, deck or grade and the box-stand 260 set to a maximum height setting such that the top of the box 240 is at a desired height relative to a sub-floor, deck or grade.

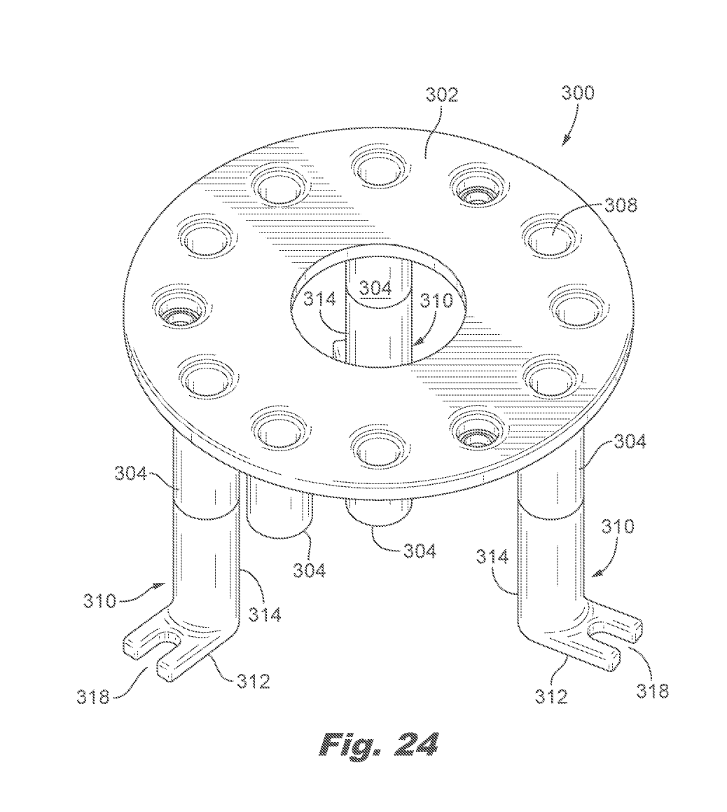

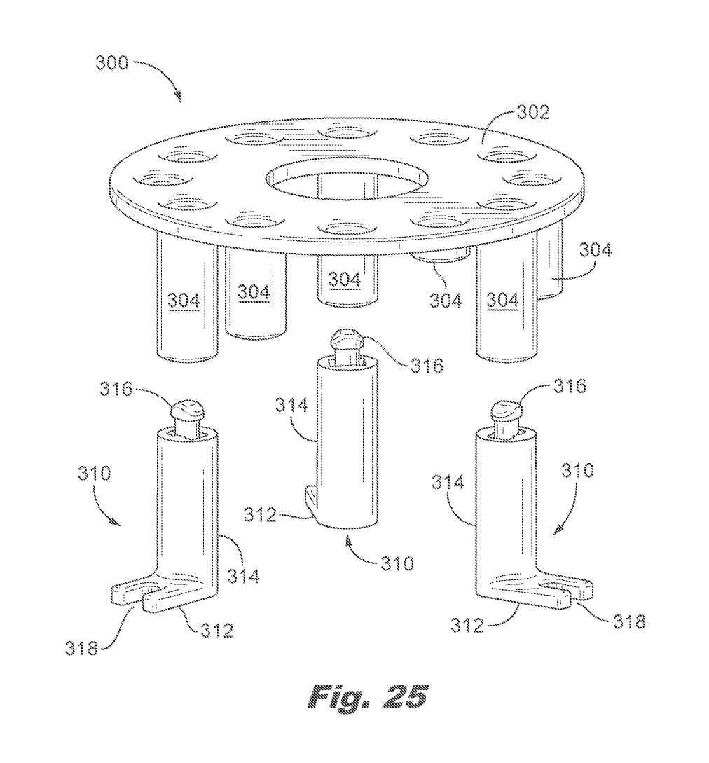

Turing to FIGS. 24-27, another exemplary embodiment of a box-stand that may be used with the box assemblies described herein is shown. In this exemplary embodiment, the box-stand 300 includes a base 302 and one or more legs 310. The base 302 has one or more leg support members 304 extending from the base 302. The leg support members 304 may be secured to or integrally formed into the base 302. In the embodiment shown, the leg support members 304 are integrally formed into the base 302. As seen in FIG. 26, the leg support members 304 are arrange in sets 306, here sets 306a, 306b and 306c. Each set 306 includes a plurality of leg support members 304, each having a different length “Lx” where Lx is a reference number. Each leg support member 304 includes an opening 308 for coupling the leg support member to a leg 310.

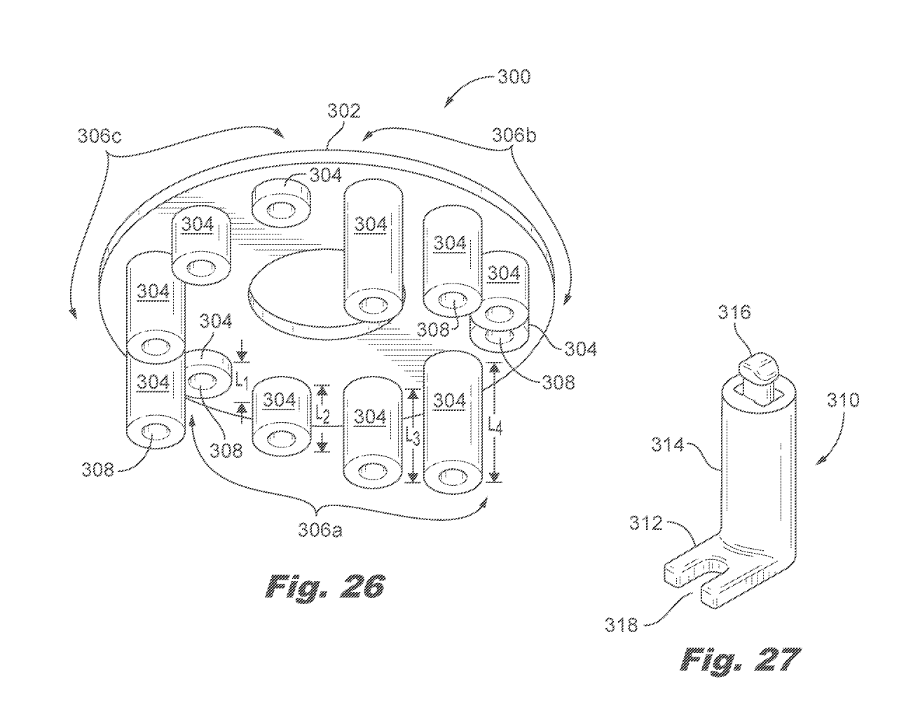

As seen in FIG. 27, each leg 310 includes a base 312, a stem 314 and a coupling pin 316. The base 312 includes a notch, slot or aperture 318 that can be used to secure the leg 310 to a sub-floor, grade or deck. When a leg 310 is inserted into the opening 308 in a leg support member 304 at a desired height, the coupling pin 316 engages the walls of the opening 308 in the leg support member 304 to create a friction fit that releasably secures the leg 310 to the leg support member 304 at the desired height setting. To release the coupling pin 316 from the opening 308 the leg is pulled with sufficient force to overcome the friction force holding the leg 310 to the leg support member 304. In the embodiment shown in FIG. 24, the height of the box-stand 300 is at a maximum height setting.

The box-stand 300 may be made of a non-metallic material, such as injection molded thermoplastic, or the box-stand 300 may be made of a metallic material, such as galvanized steel, stainless steel or aluminum. In another embodiment, the base 302 and one or more leg support members 304 may be made of a non-metallic material, and the one or more legs 310 may be made of a metallic material. In another embodiment, the base 302 and one or more leg support members 304 may be made of a metallic material, and the one or more legs 310 may be made of a non-metallic material.

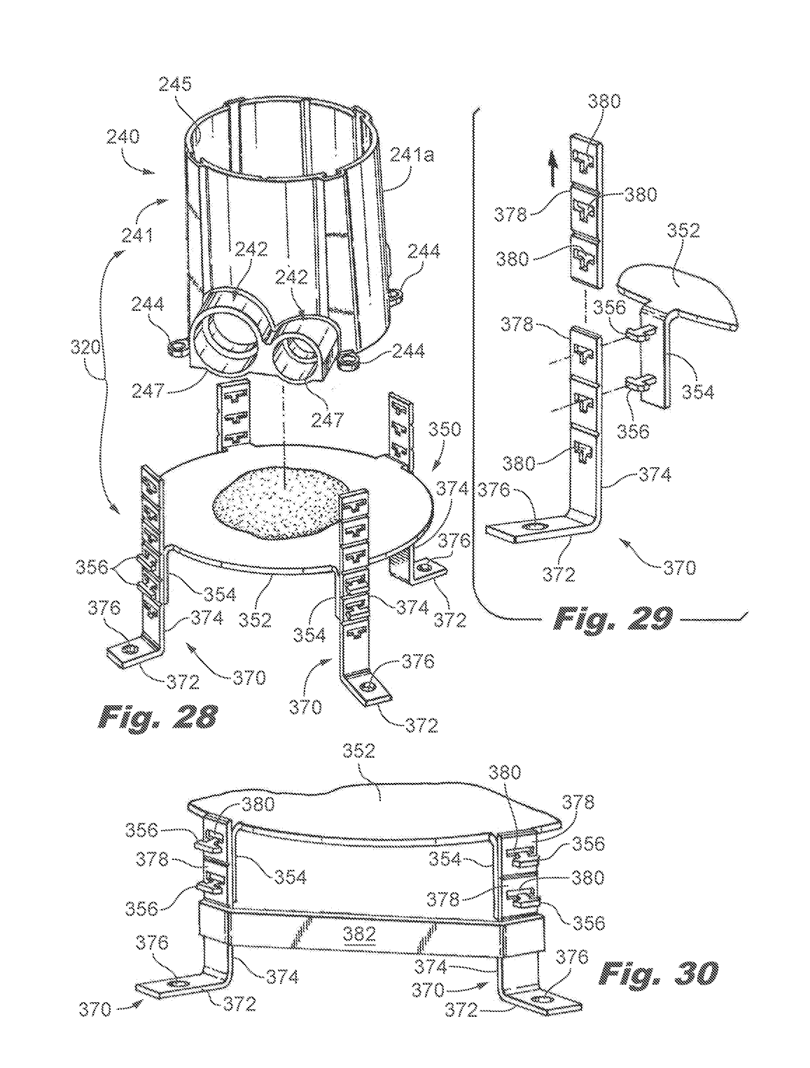

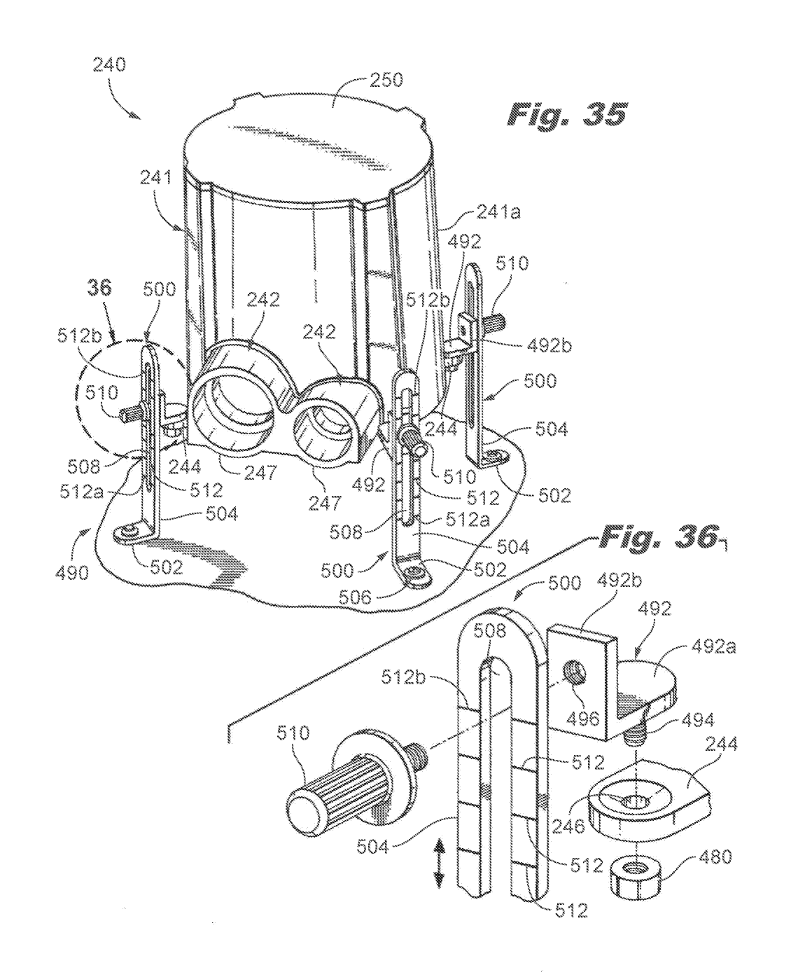

Turing to FIGS. 28-30, another exemplary embodiment of a box assembly according to the present disclosure is shown. In this embodiment, the box assembly 320 includes a box 240 and a box-stand 350. The box assembly 320 may also include a cover 250, seen in FIG. 35, that may be inserted over the top opening 245 in the box 240 prior to pouring concrete so that the concrete does not enter the box, as described above. The box 240 is described above and for ease of description is not repeated.

In this exemplary embodiment, the box-stand 350 includes a base 352 and one or more legs 370. The base 352 has one or more leg support members 354, which may be mounting arms, extending from the base 352. The one or more leg support members 354 may be secured to or integrally formed into the base 352. In the embodiment shown, the leg support members 354 are integrally formed into the base 352. Extending from the leg support members 354 are one or more coupling members 356, seen in FIG. 29. In this embodiment, the coupling members are T-shaped arms extending substantially perpendicular to the leg support member 354. The one or more coupling members 356 may be secured to or integrally formed into the leg support members 354.

Continuing to refer to FIG. 29, each leg 370 includes a base 372 and a stem 374. The base 372 includes a notch or aperture 376 that can be used to secure the leg 370 to a sub-floor, grade or deck. The stem 374 of each leg 370 includes a plurality of breakaway members 378 each having an opening 380 configured to receive a coupling member 356 in a leg support member 354. In the embodiment shown, the breakaway members 378 have a T-shaped opening 380 that has a wide portion that receives a coupling member 356 and a narrow portion that releasably holds the coupling member within the opening 380.

To set the height of the box-stand 350, the coupling members 356 are inserted into corresponding openings 380 in breakaway members 378 at a desired height so that the coupling members 356 rest within that opening 380 and engage the corresponding breakaway member 378 as seen in FIG. 29. The breakaway member or members 378 extending above the base 352 may be detached from the stem 374 by continuously bending the breakaway members so that the stem 374 is even with the base 352. To release the coupling members 356 from the opening 380, the base 352 is lifted so that the coupling members 356 can pass through the wide portion of the opening 380. To provide additional stability to the legs 370, a cross-bar 382 having coupling members, which are similar to the coupling members 356, extending from an inside surface of the cross-bar 382 may be secured to the legs 370, as seen in FIG. 30.

The box-stand 350 may be made of a non-metallic material, such as injection molded thermoplastic, or the box-stand 350 may be made of a metallic material, such as galvanized steel, stainless steel or aluminum. In another embodiment, the base 352 and one or more leg support members 354 may be made of a non-metallic material and the one or more legs 370 can be made of a metallic material. In another embodiment, the base 352 and one or more leg support members 354 may be made of a metallic material and the one or more legs 370 can be made of a non-metallic material.

Turing to FIGS. 31-34, another exemplary embodiment of a box assembly according to the present disclosure is shown. In this embodiment, the box assembly 400 includes a box 240 and a box-stand 420. The box assembly 400 may also include a cover 250 that may be inserted over the top opening 245 in the box 240 prior to pouring concrete so that the concrete does not enter the box, as described above. The box 240 is described above and for ease of description is not repeated.

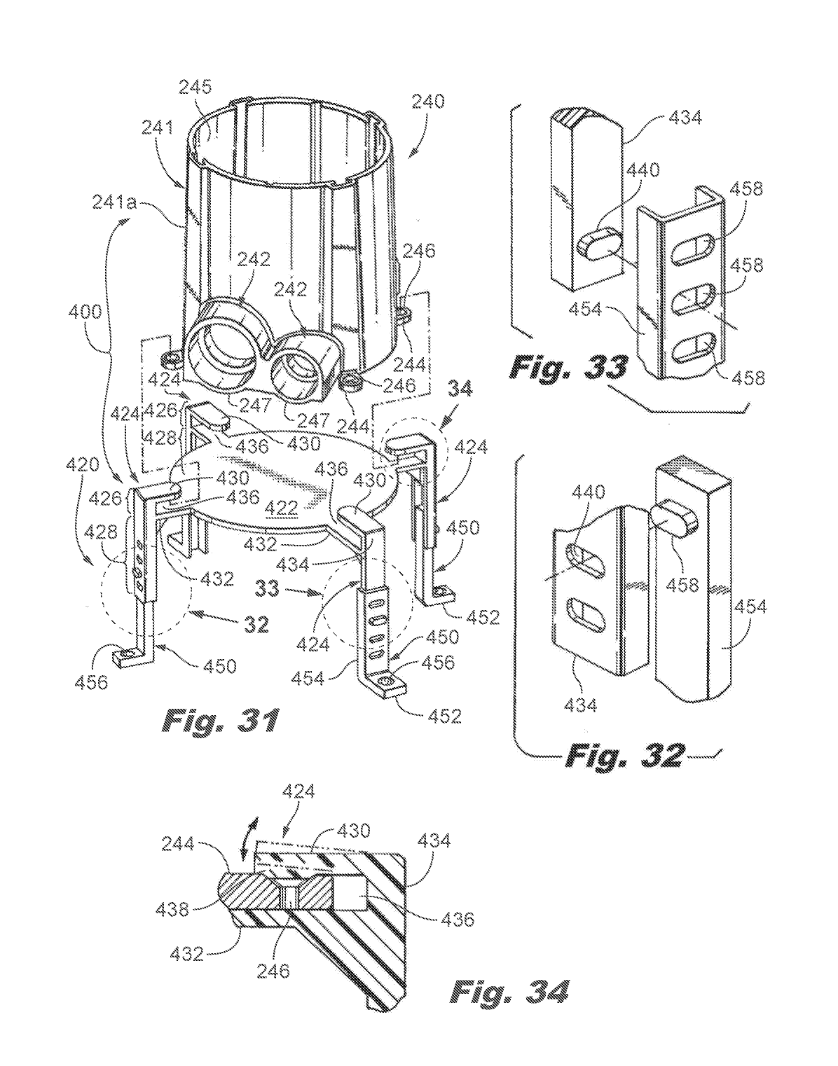

Referring to FIG. 31, in this exemplary embodiment, the box-stand 420 includes a base 422 and one or more legs 450. The base 422 has one or more leg support members 424 extending from the base. The one or more leg support members 424 may be secured to or integrally formed into the base 422. In the embodiment shown, the leg support members 424 are integrally formed into the base 422. Each leg support member 424 includes a box coupling section 426 and a leg coupling section 428. The box coupling section 426 in this exemplary embodiment includes an upper arm 430 and a lower arm 432 joined to a portion of brace 434 so that a channel 436 is formed between the upper arm and lower arm. As seen in FIG. 34, extending from the upper arm 430 into the channel 436 is a detent 438 used to releasably couple the box 410 to the box-stand 420. More specifically, when a mounting ring 244 is inserted into the channel 436, the detent 438 engages the mounting ring causing the upper arm 430 to flex upwardly until the aperture 246 in the mounting ring 244 is aligned with the detent 438 so that the upper arm 430 can return to its normal state such that the detent 438 is positioned within the aperture 246, as seen in FIG. 34. In one embodiment, the leg coupling section 428 includes one or more coupling members 440, which may be in the form of openings in the brace 434, seen in FIG. 32. In another embodiment, the leg coupling section 428 may include the remaining portion of the brace 434 and one or more coupling members 440, which may be in the form of detents extending from the brace 434, as seen in FIG. 33. The one or more detents may be secured to or integrally formed into the brace 434.

As seen in FIG. 31, each leg 450 includes a base 452 and a stem 454. The base 452 includes a notch, slot or aperture 456 that can be used to secure the leg 450 to a sub-floor, grade or deck. In one embodiment, shown in FIG. 32, the stem 454 of each leg 450 has a coupling member 458, which may be in the form of a detent, that is configured to fit within the coupling members 440 of the leg support member 424. In another exemplary embodiment, shown in FIG. 33, the stem 454 of each leg 450 includes a plurality of coupling members 458, which may be in the form of openings 456 to receive a coupling member 440, e.g., a detent, in a leg support member 424.

To set the height of the box-stand 420, the coupling members 458 of stem 454 are coupled with corresponding coupling members 440 in the brace 434 at a desired height setting. In the embodiment of FIG. 32, the opening 440 in brace 434 are coupled with detents 458 on stem 454, and in the embodiment of FIG. 33, detents 440 on brace 434 are coupled with openings 458 in stem 454. To release one coupling member from the other coupling member, the leg 540 is pivoted so that the detent can slide out of the opening 440.

The box-stand 420 may be made of a non-metallic material, such as injection molded thermoplastic, or the box-stand 420 may be made of a metallic material, such as galvanized steel, stainless steel or aluminum. In another embodiment, the base 422 and one or more leg support members 424 may be made of a non-metallic material, and the one or more legs 450 can be made of a metallic material. In another embodiment, the base 422 and one or more leg support members 424 may be made of a metallic material, and the one or more legs 450 can be made of a non-metallic material.

Turning to FIGS. 35 and 36, another exemplary embodiment of a box assembly according to the present disclosure is shown. In this embodiment, the box assembly 460 includes a box 240 and a box-stand 490. The box assembly 460 may also include a cover 250 that may be inserted over the top opening 245 in the box 240 prior to pouring concrete so that the concrete does not enter the box, as described above. The box 240 is described above and for ease of description is not repeated.

In this exemplary embodiment, the box-stand 490 includes a plurality of box-stand mounting members 492 and a plurality of corresponding legs 500. In this exemplary embodiment, the box-stand mounting members 492 are angled tabs, seen in FIG. 36, having a first end 492a and a second end 492b that is at an angle, e.g., at a 90-degree angle, relative to the first end 492a. The first end 492a has a threaded rod 494 extending therefrom and substantially perpendicular to the first end 492a of the box-stand mounting member 492. The threaded rod 494 is used to secure the box-stand mounting member 492 to the housing 241 via mounting rings 244. More specifically, the threaded rod 494 is inserted into the aperture 246 in the mounting ring 244 and a nut 480 is secured to the threaded rod 494. The second end 492b of each box-stand mounting member 492 has a threaded opening 496 used to couple a leg 500 to the box-stand mounting member 492.

Referring again to FIG. 35, each leg 500 of the box-stand 490 includes a base 502 and a stem 504. The base 502 includes a notch or aperture 506 that can be used to secure the leg 450 to a sub-floor, grade or deck. In one embodiment, the stem 504 of each leg 500 has an elongated slot 508 through which a bolt 510, seen in FIG. 36, may pass and be inserted into the threaded opening 496 in the second end 492b of the box-stand mounting member 492. The stem 504 may also include a plurality of markings or indicia 512 that are positioned along the slot 508. The plurality of markings or indicia 512 may be used to provide a general reference for leveling the box 240 and/or for setting a height of the box-stand 490. For example, if the base 502 of each leg 500 is set to the 4^{th} marking down from the top marking 512b, as seen in FIG. 35, the box 240 will likely be level if the sub-floor, deck or grade is level. In another embodiment, the plurality of markings or indicia 512 may reflect a predefined distance between the marking 512 and the base 502 of the leg 500. For example, the lower marking 512a may represent a predefined distance between the marking and the bottom of the base 502 of 2.5 inches, and the subsequent markings 512 could be set at ½ inch intervals.

The box-stand 490 may be made of a non-metallic material, such as injection molded thermoplastic, or the box-stand 490 may be made of a metallic material, such as galvanized steel, stainless steel or aluminum. In another embodiment, the base 502 of each leg 500 may be made of a non-metallic material and the stem 504 of each leg 500 may be made of a metallic material. In another embodiment, the base 502 of each leg 500 may be made of a metallic material and the stem 504 of each leg 500 may be made of a non-metallic material.

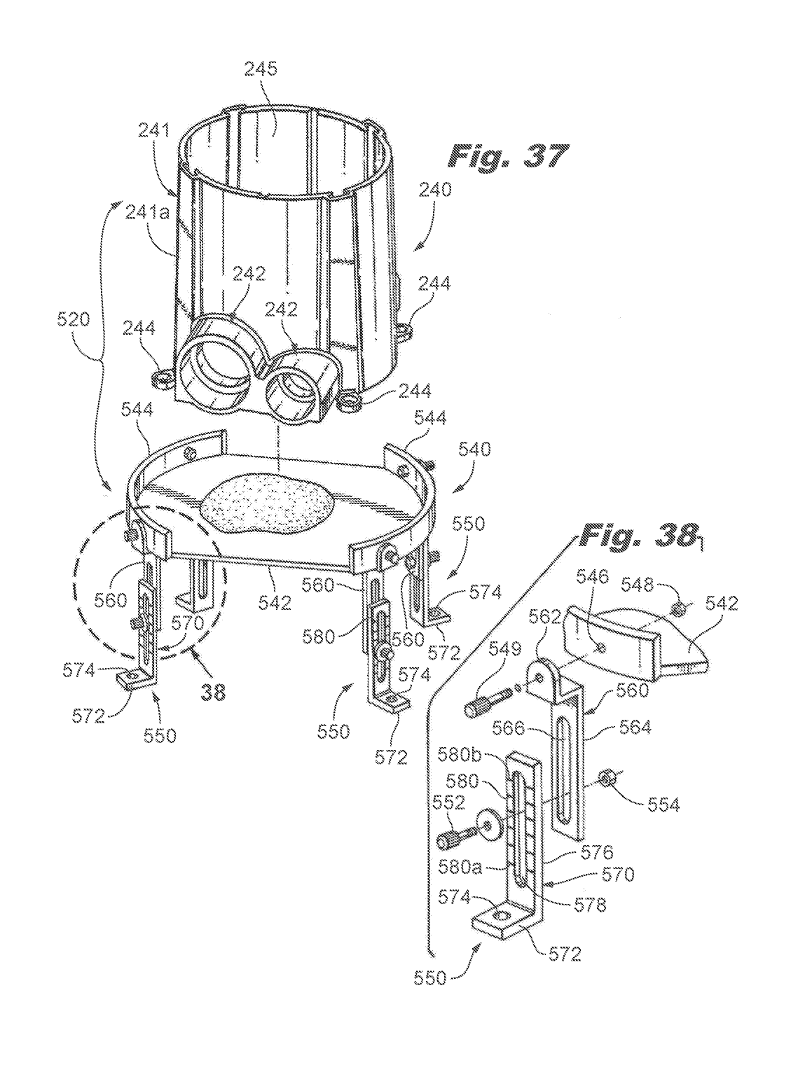

Referring to FIGS. 37 and 38, another exemplary embodiment of a box assembly according to the present disclosure is shown. In this embodiment, the box assembly 520 includes a box 240 and a box-stand 540. The box assembly 520 may also include a cover 250 may be inserted over the top opening 245 in the box 240 prior to pouring concrete so that the concrete does not enter the box, as described above. The box 240 is described above and for ease of description is not repeated.

In this exemplary embodiment, the box-stand 540 includes a base 542 and one or more legs 550. The base 542 has one or more raised edges 544, seen in FIG. 37, to align the box 240 with the box-stand base 542. The raised edge 544 includes one or more apertures 546 used to secure the legs 550 to the base 542. The first stem 560 is secured to the base 542. In the embodiment shown, the leg support members 546 are secured to the raised edge 544 of the base 542 using a nut and bolt as shown in FIG. 38.

Each leg 550 of the box-stand 540 includes a first stem 560 and a second stem 570. The first stem 560 has a base connecting member 562 at one end and an elongated arm 564 extending from the base connecting member 562. The elongated arm 564 has an elongated slot 566. In the embodiment shown, the base connecting member 562 is secured to the raised edge 544 of the base 542 using a nut 548 and bolt 549 as shown in FIG. 38. The second stem 570 has a base 572 at one end and an elongated arm 576 extending from the base 572. The elongated arm 576 has an elongated slot 578. The base 572 of the second stem 570 includes a notch, slot or aperture 574 that can be used to secure the leg 550 to a sub-floor, deck or grade. The elongated arm 576 of the second stem 570 may also include a plurality of markings or indicia 580 positioned along the elongated arm 576 relative to the elongated slot 578 as shown in FIG. 38. The plurality of markings or indicia 580 may be used to provide a general reference for leveling the box 240. For example, if a bottom edge 564a of the elongated arm 564 of the first stem 560 is set to the 4^{th} marking down from the top marking 580b, as seen in FIG. 38, the box 240 will likely be level if the sub-floor, grade or deck is level. In another embodiment, the plurality of markings or indicia 580 may reflect a predefined distance between a marking 580 and the base 572 of the second stem 570. For example, the lower marking 580a may represent a predefined distance between the marking and the bottom of the base 572 of about 2.5 inches, and the subsequent markings 580 could be set at ½ inch intervals.

To set the height of the box-stand 540, the slot 578 in the second stem 570 of the leg 550 is aligned with the slot 566 in the elongated arm 564 of the first stem 560. A bolt 552 is passed through the elongated slot 578 in the second stem 570 and through the elongated slot 566 in the first stem 560, and threaded into nut 554. The stems are then moved relative to each other to a desired height setting, and the nut 554 and bolt 552 are tightened.

The box-stand 540 may be made of a non-metallic material, such as injection molded thermoplastic, or the box-stand 540 may be made of a metallic material, such as galvanized steel, stainless steel or aluminum. In another embodiment, the base 542 may be made of a non-metallic material and the one or more legs 550 can be made of a metallic material. In another embodiment, the base 542 may be made of a metallic material and the one or more legs 550 can be made of a non-metallic material.

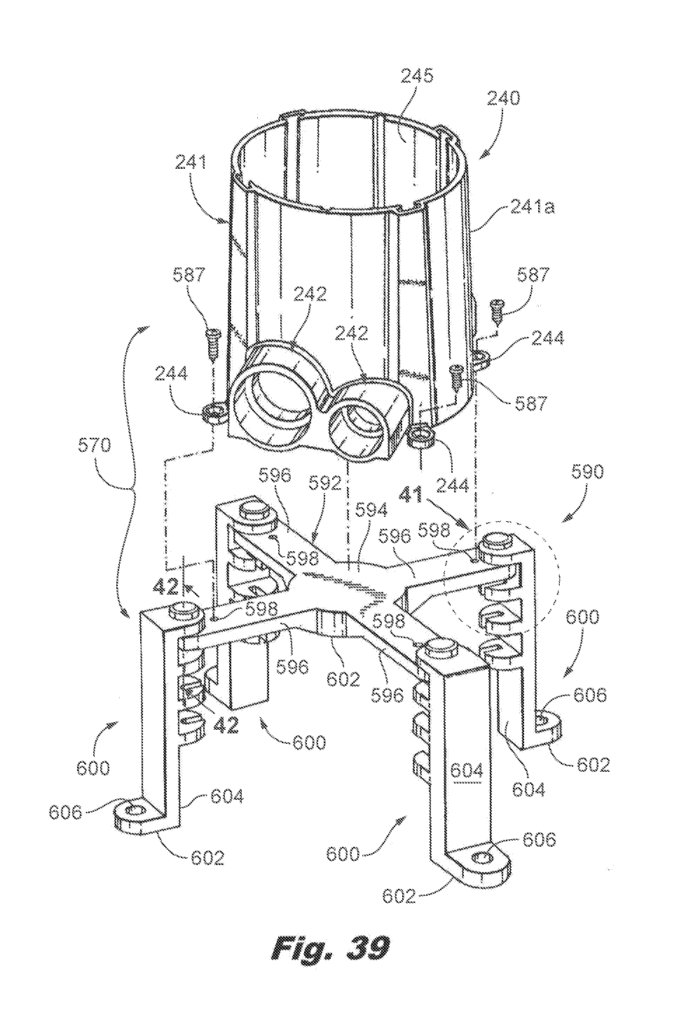

Referring to FIGS. 39-42, another exemplary embodiment of a box assembly according to the present disclosure is shown. In this exemplary embodiment, box assembly 570 includes a box 240 and a box-stand 590. The box assembly 570 may also include a cover 250, seen in FIG. 23, that may be inserted over the top opening 245 in the box 240 prior to pouring concrete so that the concrete does not enter the box. The box 240 is described above and for ease of description is not repeated. Continuing to refer to FIGS. 39-42, the box-stand 590 includes a base 592 and one or more legs 600 that can be coupled to the base 592. The base 592 includes a central hub 594 and a plurality of leg support members 596 extending from the central hub 594. The central hub 544 and leg support members 596 are used to support and secure the box 240 to the box-stand 590 and to secure the one or more legs 600 to the base 592. At a free end of each leg support member 596 are a pair of mounting apertures 598 and 599. Mounting aperture 598 is used to secure the box 240 to the base 592, and mounting aperture 599 is used to secure a leg 600 to the base. In the exemplary embodiment shown, each leg 600 includes a base 602 and a stem 604. The base 602 includes a notch, slot or aperture 606 that can be used to secure the leg 600 to a sub-floor, deck or grade using for example fasteners, such as nails, screws, or spikes. The stem 604 includes a plurality of height adjustment ledges 608 configured to be attached to a leg support member 596 extending from the central hub 594. Each height adjustment ledge 608 includes a slot or aperture 610, seen in FIG. 41, used to secure the leg support member 596 to the height adjustment ledge.

The box-stand 590 may be made of a non-metallic material, such as injection molded thermoplastic, or the box-stand 590 may be made of a metallic material, such as galvanized steel, stainless steel or aluminum. In another embodiment, the base 592 may be made of a non-metallic material and the one or more legs 600 can be made of a metallic material. In another embodiment, the base 592 may be made of a metallic material and the one or more legs 600 can be made of a non-metallic material.

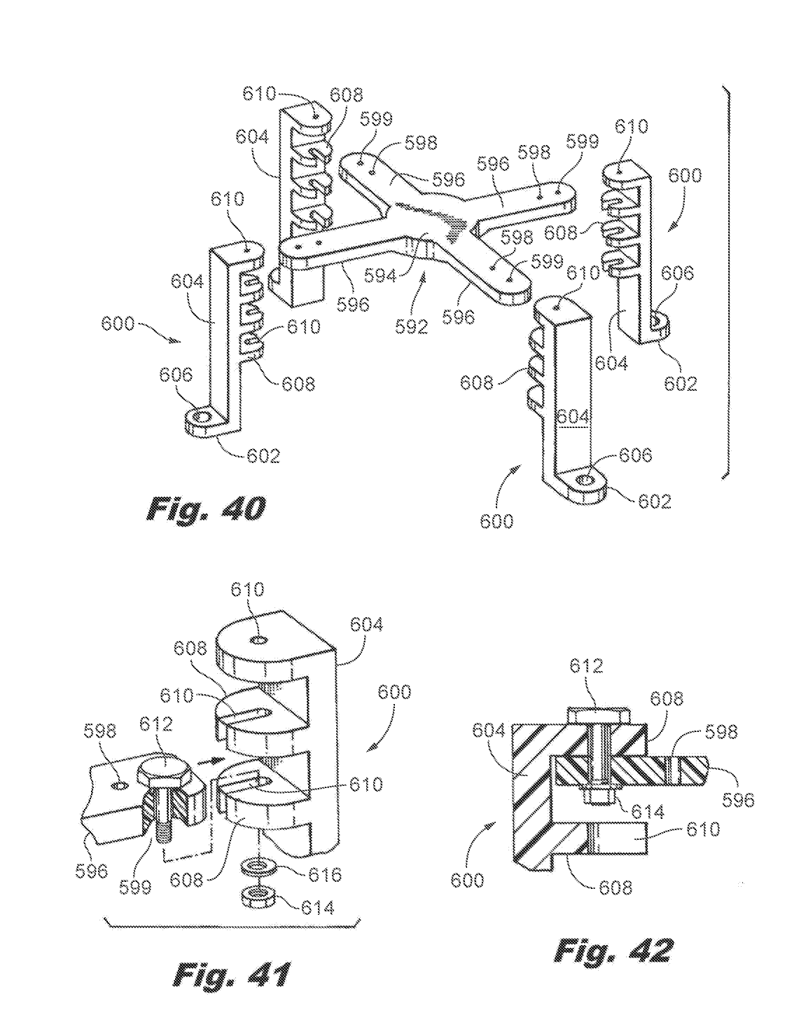

The box 240 is secured to the box-stand 590 in this exemplary embodiment using fasteners, such as machine screws. More specifically, the box 240 is placed on the base 592 so that the mounting rings 244 are aligned with mounting apertures 598 on the leg support members 596. Screws 587 are then passed through the mounting rings 244 into the mounting apertures 598 and tightened to secure the box to the box-stand. The box-stand 590 according to the present disclosure is configured to permit adjustment of the height setting of the box 240 relative to a sub-floor, deck or grade. In the exemplary embodiment shown, the height setting of the box 240 relative to a sub-floor, deck or grade is determined by which height adjustment ledge 608 is used. Referring to FIGS. 40-42, to secure a leg 600 to a leg support member 596 at the desired height setting, the leg support member is positioned on or below a height adjustment ledge 608 such that a mounting aperture 599, seen in FIG. 40, in the leg support member 596 is aligned with the mounting slot or aperture 610 in the height adjustment ledge 608, as shown in FIG. 41. A bolt 612 is inserted through the mounting aperture 599 and through the mounting slot 610 and secured to a nut 614 and washer 616, as shown in FIG. 42.

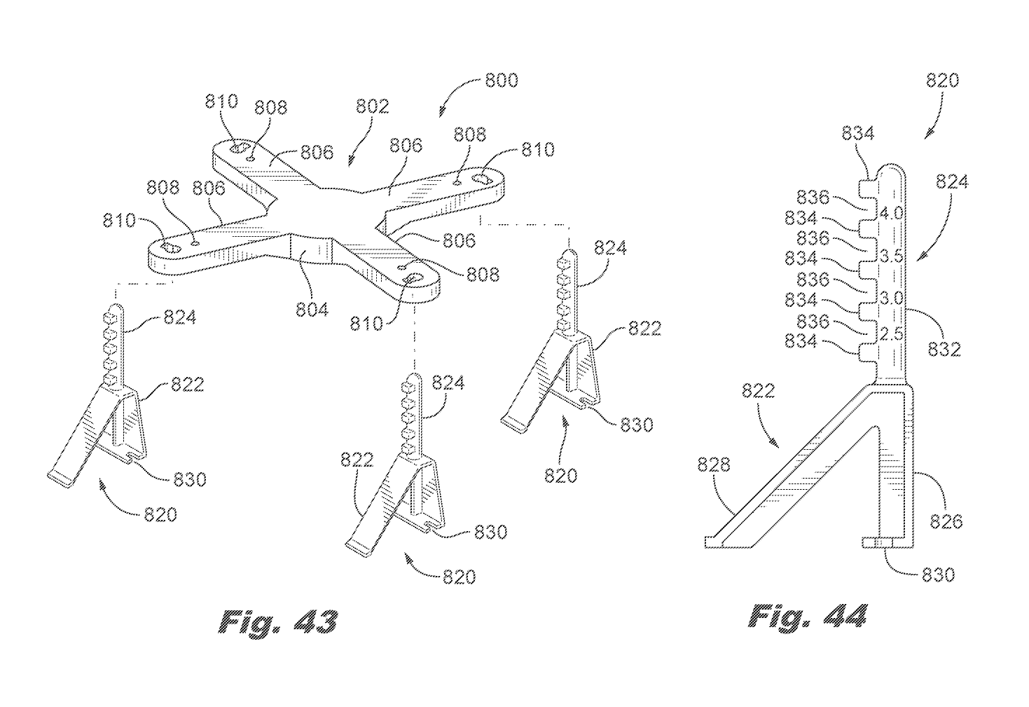

Referring to FIGS. 43-46, another exemplary embodiment of a box stand 800 that may be used with the box assemblies described herein is shown. In this exemplary embodiment, the box-stand 800 includes a base 802 and one or more legs 820 that can be coupled to the base 802. The base 802 includes a central hub 804 and a plurality of leg support members 806 extending from the central hub 804. The central hub 804 and leg support members 806 are used to support and secure a box, e.g., box 240 described above, to the box-stand 800 and to secure the one or more legs 820 to the base 802. More specifically, at a distal end of each leg support member 806 is a mounting aperture 808 that is used to secure the box to the base 802. A box, e.g., box 240, can be secured to the base 802 in this exemplary embodiment using fasteners, such as machine screws. At the distal end of each leg support member 806 is also a leg mounting aperture 810 that is used to secure a leg 820 to the base 802. In this exemplary embodiment, the leg mounting aperture 810 is formed as a keyhole shaped aperture to receive and releasably secure a leg 820 to the base 802, as shown in FIG. 43.

Referring to FIG. 44, in the exemplary embodiment shown, each leg 820 includes a support member 822 and a base connecting member 824. The support member 822 has a main support member 826 and a stabilizing member 828 that is angled relative to the main support member. The main support member includes one or more notches or apertures 830 that can be used to secure the leg 820 to a sub-floor, deck or grade using for example fasteners, such as nails, screws, or spikes. The base connecting member 824 includes a stem 832 having a plurality of height adjustment ledges 834 configured to fit through the leg mounting aperture 810 in the leg support member 806. The spacing 836 between the height adjustment ledges 834 defines the height setting of the leg 820 relative to the base 802. To provide a visual indication of the height setting of the leg 820, the stem 832 may include markings, nomenclature or other indicia representing a specific height setting. For example, the stem 832 shown in FIG. 44 includes four height settings ranging between 2.5 inches and 4.0 inches, where the space 836 closest to the support member 822 represents a height setting of 2.5 inches and the space 836 furthest from the support member represents a height setting of 4.0 inches. The number of markings on the stem 832 depends upon the length of the stem such that a longer stem may have markings ranging from between for example 2.5 inches and 10 inches.

The box-stand 800 may be made of a non-metallic material, such as injection molded thermoplastic, or the box-stand 800 may be made of a metallic material, such as galvanized steel, stainless steel or aluminum. In another embodiment, the base 802 may be made of a non-metallic material and the one or more legs 820 can be made of a metallic material. In another embodiment, the base 802 may be made of a metallic material and the one or more legs 820 can be made of a non-metallic material.

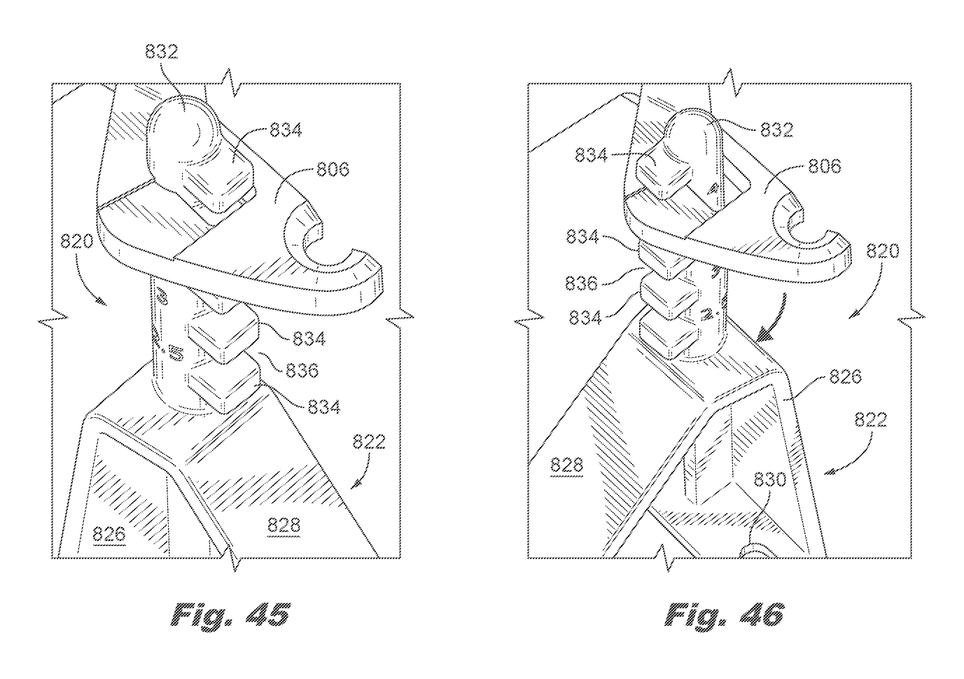

As noted, the box-stand 800 is configured to permit adjustment of the height setting of a box, e.g., box 240, relative to a sub-floor, deck or grade. In the exemplary embodiment shown in FIGS. 43-46, the height setting of the box relative to a sub-floor, deck or grade is determined by which height adjustment ledge 834 is used. Further, like other embodiments contemplated by the present disclosure, the different height settings for the legs 820 also permit adjustment to inconsistencies in the sub-flooring, decking or grade. For example, if a sub-floor, deck or grade were uneven, one ledge 834 of one leg 820 may be used and a different ledge 834 of a different leg 820 may be used to level the box. Referring to FIGS. 45 and 46, to secure a leg 820 to a leg support member 806 at the desired height setting, the stem 832 of the base connecting member 824 is positioned relative to the leg mounting aperture 810 so that the height adjustment ledges 834 and stem 832 are aligned to pass through the leg mounting aperture, as shown in FIG. 45. The stem 832 is then passed through the leg mounting aperture 810 until the space 836 representing the desired height setting is within the leg mounting aperture. The leg 820 is then rotated, e.g., clockwise, so that the leg support member 806 of base 802 is positioned in the space 836 of the stem 832 representing the desired height setting thus locking the position of the leg 820 relative to the base 802, as shown in FIG. 46.

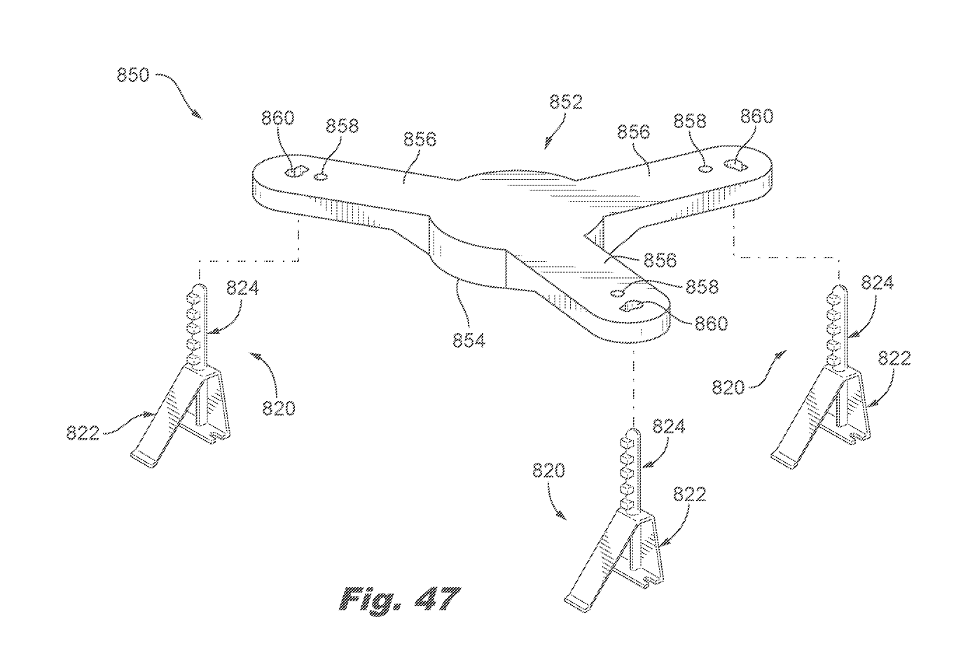

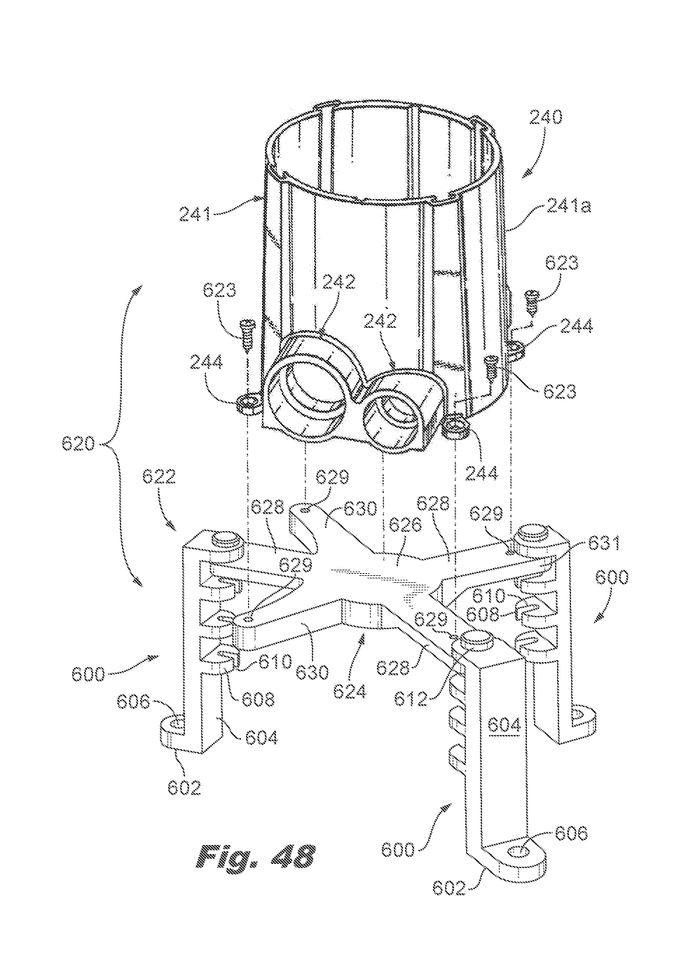

Referring to FIG. 47, another exemplary embodiment of a box-stand 850 that may be used with the box assemblies described herein is shown. In this exemplary embodiment, the box-stand 850 is similar to the box-stand 800 except that this box-stand has three leg support members. More specifically, the box-stand 850 includes a base 852 and three legs 820 that can be coupled to the base 852. The base 852 includes a central hub 854 and three leg support members 856 extending from the central hub 854. The leg support members 856 are used to support and secure a box, e.g., box 240 described above, to the box-stand 850 and to secure the three legs 820 to the base 852. At a distal end of each leg support member 856 is a mounting aperture 858 that can be used to secure the box to the base 852. A box, e.g., box 240, can be secured to the base 852 in this exemplary embodiment using fasteners, such as machine screws into mounting apertures 858. At the distal end of each leg support member 856 is also a leg mounting aperture 860 that is used to secure a leg 870 to the base 852. The leg mounting aperture 860 is formed as a keyhole shaped aperture to receive and releasably secure each leg 820 to the base 852. In the exemplary embodiment shown in FIG. 48, the legs 820 and securing the legs 820 to the legs to a leg support member are described above and for ease of description are not repeated. Also, the box-stand 850 may be made of a non-metallic material, such as injection molded thermoplastic, or the box-stand 850 may be made of a metallic material, such as galvanized steel, stainless steel or aluminum. In another embodiment, the base 852 may be made of a non-metallic material and the three legs 870 can be made of a metallic material. In another embodiment, the base 852 may be made of a metallic material and the three legs 870 can be made of a non-metallic material.

Referring to FIG. 48, another exemplary embodiment of a box assembly according to the present disclosure is shown. In this exemplary embodiment, box assembly 620 is substantially similar to the box assembly 570 of FIG. 39. In this exemplary embodiment, the box assembly includes box 240, which is described above and for ease of description is not repeated, and box-stand 622. The box-stand 622 includes a base 624 and one or more legs 600 that can be coupled to the base 624. The box-stand 622 may be made of a non-metallic material, such as injection molded thermoplastic, or the box-stand 622 may be made of a metallic material, such as galvanized steel, stainless steel or aluminum. The legs 600 in this exemplary embodiment are the same as the legs described above with reference to FIGS. 39-42 and for ease of description are not repeated.

The base 624 includes a central hub 626 and a plurality of leg support members 628 extending from the central hub 626, here three leg support members 628. The leg support members 628 are used in part to secure the box 240 to the box-stand 622 and to secure the legs 600 to the base 624. The central hub 626 also has one or more box support members 630 extending from the central hub 626, here two box support members 630. The box support members 630 are used to secure the box 240 to the base 624. As described above, the box 240 is secured to the box-stand 622 in this exemplary embodiment using fasteners, such as machine screws 623. More specifically, the housing 241 of box 240 is placed on the base 624 so that the mounting rings 244 are aligned with mounting apertures 629 on two of the leg support members 628 and the box support members 630. Screws 623 are then passed through the mounting rings 244 into the mounting apertures 629 and tightened to secure the box to the box-stand. In this embodiment, because there are three legs 600 that get secured to three leg support members, the three leg support members do not align with the four mounting rings 244 on the box 240. To secure the housing 241 of the box 240 to the box-stand it is preferred to use the four mounting rings 244 so that box support members 630 are added to the base 624.

Continuing to refer to FIG. 48, at a free end of each leg support member 628 are a pair of mounting apertures 629 and 631. Mounting apertures 629 are used to secure the housing 241 to the base 624, and mounting apertures 631 are used to secure a leg 600 to the base. In the exemplary embodiment shown, each leg 600 includes a base 602 and a stem 604. The base 602 includes a notch, slot or aperture 606 that can be used to secure the leg 600 to a sub-floor, deck or grade using for example fasteners, such as nails, screws, or spikes. The stem 604 includes a plurality of height adjustment ledges 608 configured to be attached to a leg support member 596 extending from the central hub 626. Each height adjustment ledge 608 includes a slot or aperture 610 used to secure the leg support member 628 to the height adjustment ledge.

The box-stand 622 according to the present disclosure is configured to permit adjustment of the height of the box 240 relative to a sub-floor, deck or grade. In the exemplary embodiment shown, the height of the box 240 relative to a sub-floor, deck or grade is determined by which height adjustment ledge 608 is used. To secure a leg 600 to a leg support member 628 at the desired height setting, the leg support member is positioned on or below a height adjustment ledge 608 such that a mounting aperture 631 in the leg support member 628 is aligned with the mounting slot or aperture 610 in the height adjustment ledge 608. A bolt 612 is inserted through the mounting aperture 631 and through the mounting slot 610 and secured to a nut 614 and washer 616 as described above.

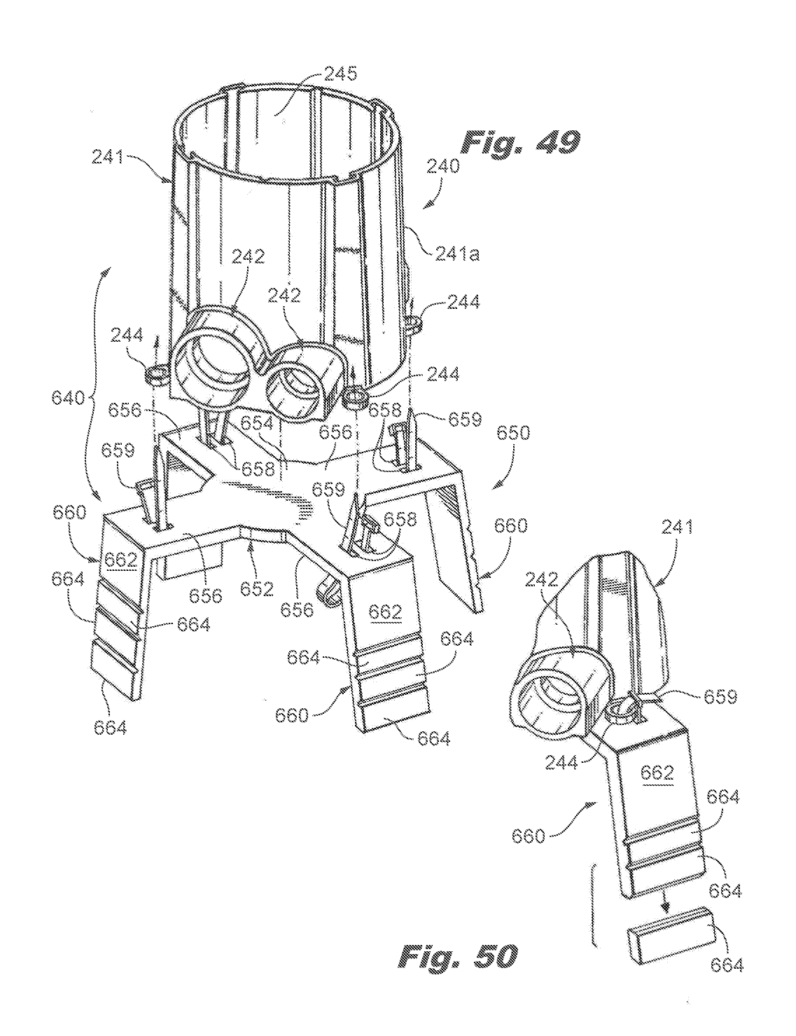

Referring to FIGS. 49 and 50, another exemplary embodiment of a box assembly according to the present disclosure is shown. In this embodiment, the box assembly 640 includes a box 240 and a box-stand 650. In this exemplary embodiment, the box 240 is described above and for ease of description is not repeated. The box-stand 650 includes a base 652 and one or more legs 660. The base 652 includes a central hub 654 and plurality of leg support members 656 extending from the central hub 654. The leg support members 656 are used to support and secure the housing 241 of the box 240 to the box-stand 650 and to secure legs 660 to the base 652. Each leg support member 656 includes a pair of slots 658 that receive a fastener 659, such as a tie-wrap, used to secure the housing 241 to the box-stand 650. More specifically, the housing 241 is placed on the base 652 and a tie-wrap 659 is looped through the slots 658, as seen in FIG. 49, and through the mounting ring 244 on the housing 241 and tightened to secure the box to the box-stand, as seen in FIG. 50. In this embodiment, the legs 660 of the box-stand 650 are integrally formed into the leg support members 656 and arranged so that they are at an angle relative to the leg support member to better support the box 240. As seen in FIG. 50, each leg 660 has a stem 662 that includes a plurality of breakaway members 664 used to adjust the height setting for the box-stand 650.

The box-stand 650 may be made of a non-metallic material, such as injection molded thermoplastic, or the box-stand 650 may be made of a metallic material, such as galvanized steel, stainless steel or aluminum. In another embodiment, the base 652 may be made of a non-metallic material and the legs 660 can be made of a metallic material. In another embodiment, the base 652 may be made of a metallic material and the legs 660 can be made of a non-metallic material.

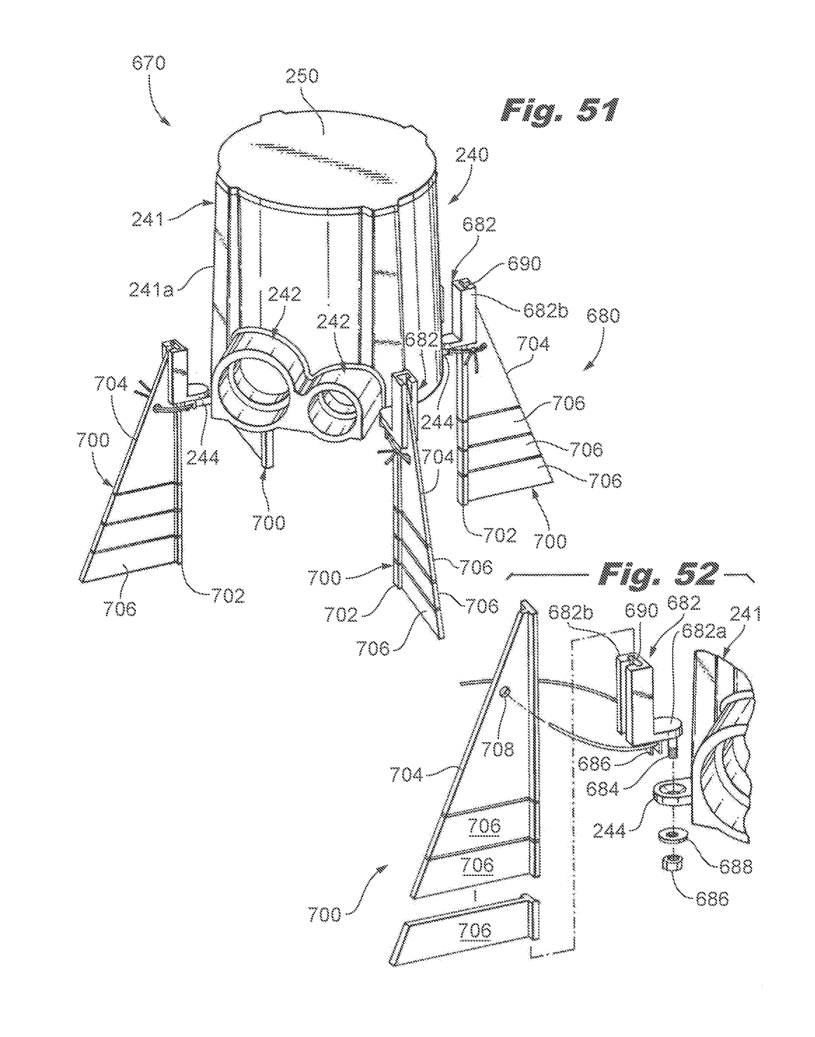

Referring to FIGS. 51 and 52, another exemplary embodiment of a box assembly according to the present disclosure is shown. In this embodiment, the box assembly 670 includes a box 240 and a box-stand 680. In this exemplary embodiment, the box 240 is described above and for ease of description is not repeated. The box-stand 680 includes a plurality of box-stand mounting members 682 and a corresponding plurality of legs 700. In this exemplary embodiment, the box-stand mounting members 682 are angled tabs, seen in FIG. 52, having a first end 682a and a second end 682b that is at an angle, e.g., at a 90-degree angle, relative to the first end 682a. The first end 682a has a threaded rod 684 extending therefrom and substantially perpendicular to the first end 682a of the box-stand mounting member 682. The first end 682a may also include a track 686 to facilitate further securing the box-stand mounting member 682 to a leg 700. The threaded rod 684 is used to secure the box-stand mounting member 682 to the housing 241 of the box 240 via mounting rings 244. More specifically, the threaded rod 684 is inserted into an aperture in the mounting ring 244 and a nut 686 and washer 688 are secured to the threaded rod 684. The second end 682b of each box-stand mounting member 682 has a shaped opening 690, e.g., a T-shaped opening, used to couple a leg 700 to the box-stand mounting member 682.

Each leg 700 of the box-stand 680 includes spline 702 integrally formed into or attached to a body 704 such that the joint between the spline 702 and the body 704 forms a shape, e.g., a T-shape, capable of mating with the shaped opening 690 in the box-stand mounting member 682 to releasably secure the leg to the box-stand mounting member. To further secure the leg 700 to the box-stand mounting member 682, a cable, string, tie-wrap or other fastener can be passed through aperture 708 in body 704 and through the track 686 in the box-stand mounting member 682 and tightened as shown in FIG. 51.

The body 704 may come in many shapes, such as a triangular shape, as seen in FIG. 51, or a rectangular shape, or any other shape sufficient to support the box 240. As seen in FIG. 52, each leg 700 includes a plurality of breakaway members 706 used to adjust the height setting for the box-stand 680. In the embodiment shown, a portion of the body 704 and a portion of the spline 702 form each breakaway member 706.

The box-stand 680 may be made of a non-metallic material, such as injection molded thermoplastic, or the box-stand 680 may be made of a metallic material, such as galvanized steel, stainless steel or aluminum. In another embodiment, the box-stand mounting member 682 may be made of a non-metallic material and the legs 700 can be made of a metallic material. In another embodiment, the box-stand mounting member 682 may be made of a metallic material and the legs 700 can be made of a non-metallic material.

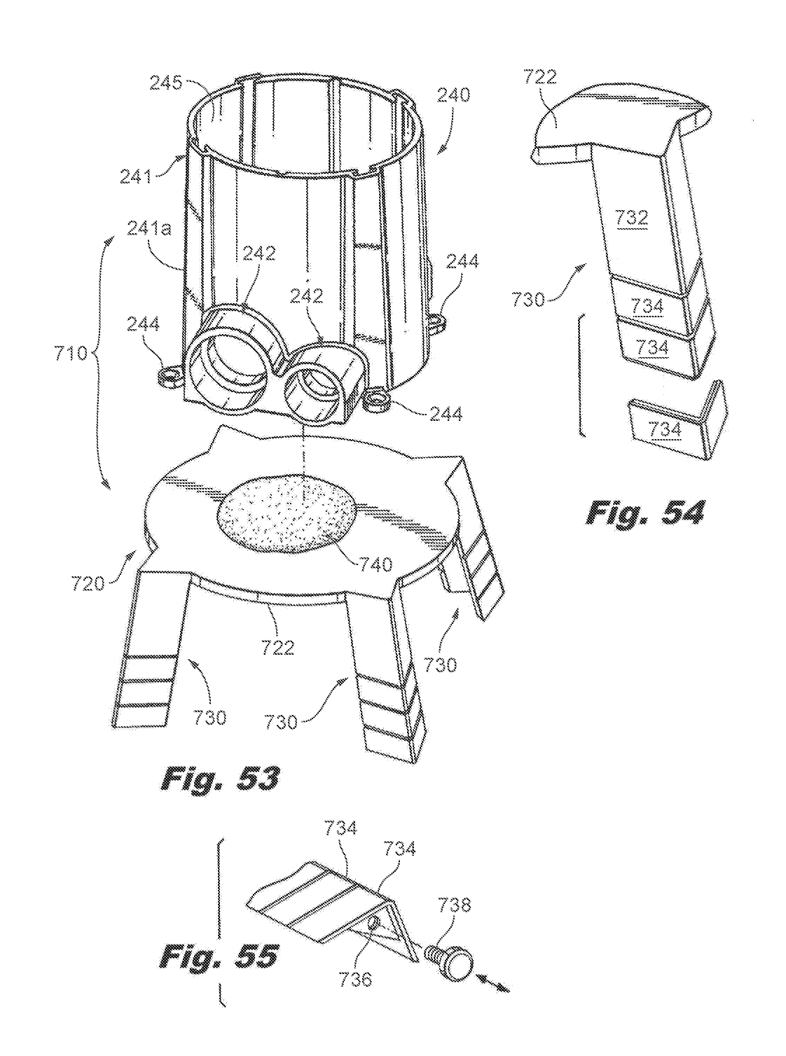

Referring to FIGS. 53-55, another exemplary embodiment of a box assembly according to the present disclosure is shown. In this embodiment, the box assembly 710 includes a box 240 and a box-stand 720. The box 240 is the same as the box described above and for ease of description is not repeated. The box-stand 720 includes a base 722 and one or more legs 730 extending from the base. In this embodiment, the legs 73 of the box-stand 720 are integrally formed into the base 722 and arranged so that they are at an angle relative to the base to better support the box 240. As seen in FIG. 54, each leg 730 has a stem 732 that includes a plurality of breakaway members 734 used to adjust the height setting of the box-stand 720. The breakaway members 734 may be separated from the stem 732 by bending the breakaway until it separates from the stem. As seen in FIG. 55, each breakaway 734 may include a threaded aperture 736 so that a threaded height adjustment member 738, such as a bolt or screw, may be added to the last breakaway member 734 and adjusted to set the height of the box 240. In this embodiment, the box 240 may be secured the base 722 using an adhesive 740, such as a PVC glue, double sided tape, a hook and loop type fastener, mechanical fasteners or other type of fasteners.

The box-stand 720 may be made of a non-metallic material, such as injection molded thermoplastic, or the box-stand 720 may be made of a metallic material, such as galvanized steel, stainless steel or aluminum. In another embodiment, the base 722 may be made of a non-metallic material and the legs 730 may be made of a metallic material. In another embodiment, the base 722 may be made of a metallic material and the legs 730 may be made of a non-metallic material.

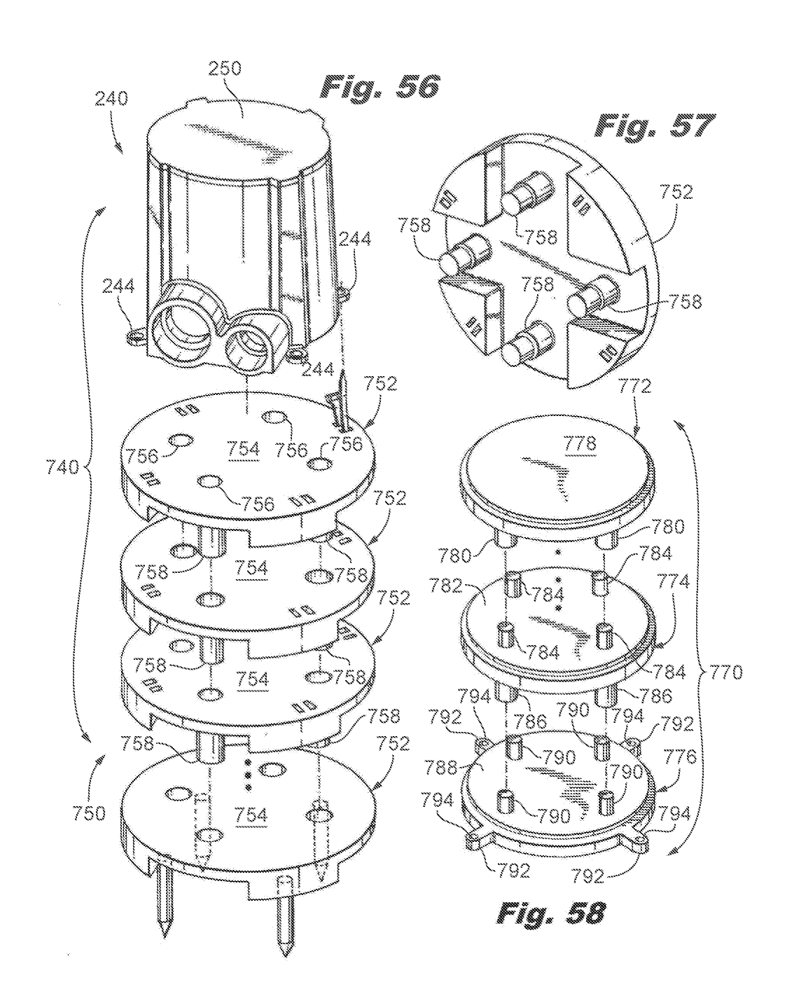

Referring to FIGS. 56 and 57, another exemplary embodiment of a box assembly according to the present disclosure is shown. In this embodiment, the box assembly 740 includes a box 240 and a box-stand 750. In this exemplary embodiment, the box 240 is described above and for ease of description is not repeated. The box-stand 750 includes one or more plates 752 that can be stacked one upon the other and coupled together to provide the desired height setting for the box 240. Each plate 752 may come in many different shapes, such as circular or round, square or rectangular, or any other shape sufficient to support the box 240. For example, the round box 240, shown in FIG. 56, would best fit on round plates 752. In instances where the box 240 is a square box, the box would best fit on a square plate. In the embodiment shown, each plate is a round plate that conforms to the circular bottom of the box 240. The top surface 754 of each plate 752 is a flat surface for the box to rest upon. As noted, the plates 572 may be stacked one upon the other to achieve the desired height setting for the box 240. To stack the plates 752 together, the plates may be coupled using various types of quick fit structures. In this exemplary embodiment, each plate 752 includes one or more bosses 758 extending from a bottom surface of the plate and having an aperture 756 through the plate and boss. Each boss is configured to mate with a corresponding aperture 756 in an adjacent plate 752 as the plates are pressed together. The plates 752 may have channels, openings and/or passageways and/or perforations that allow concrete to pass thru the plates when concrete is poured. Allowing the concrete to pass through the plates binds the plates to the concrete to provide a more stable platform for the box.

In another exemplary embodiment shown in FIG. 58, the box-stand 770 has three plate types, a top plate 772, one or more intermediate plates 774 and a bottom plate 776. To stack the plates 772, 774 and 776 together, the plates may be coupled using various types of quick fit structures. In this exemplary embodiment, the top plate 772 has a flat top surface 778 for the box to rest upon and one or more bosses 780 extending from a bottom surface of the top plate. The one or more intermediate plates 774 have a top surface 782 with one or more ribs 784 extending therefrom and one or more bosses 786 extending from a bottom surface of the top plate. The ribs 784 are configured to mate with the bosses 780 extending from the top plate 772 or bosses 786 extending from another intermediate plate 774. The bottom plate 776 has a top surface 788 with one or more ribs 790 extending therefrom and one or more mounting tabs 792 extending from a side wall of the plate 776. Each mounting tab 792 has a mounting aperture 794 through which a fastener, such as a screw, nail or spike can be passed to secure the plate 776 and thus the box-stand 770 to sub-flooring, decking or grade.

In either embodiment of FIGS. 56 and 57 or FIG. 58, the successive stacking plates may interlock with each other by, for example, tongue and groove joints, dovetail joints, slot and tab joints, or bosses fitting onto ribs as described. Further, the very bottom plate that is to be in contact with grade, sub-flooring or decking may have, for example, integral spikes, as shown in FIG. 56, or mounting tabs with mounting apertures through which fasteners such as screws, nails or spikes can be driven to anchor the last plate to grade, sub-flooring or decking. In addition, each plate 752 or plates 772, 774 and 776 may be made of a non-metallic material, such as injection molded thermoplastic, or each plate 752 or plates 772, 774 and 776 may be made of a metallic material, such as galvanized steel, stainless steel or aluminum.

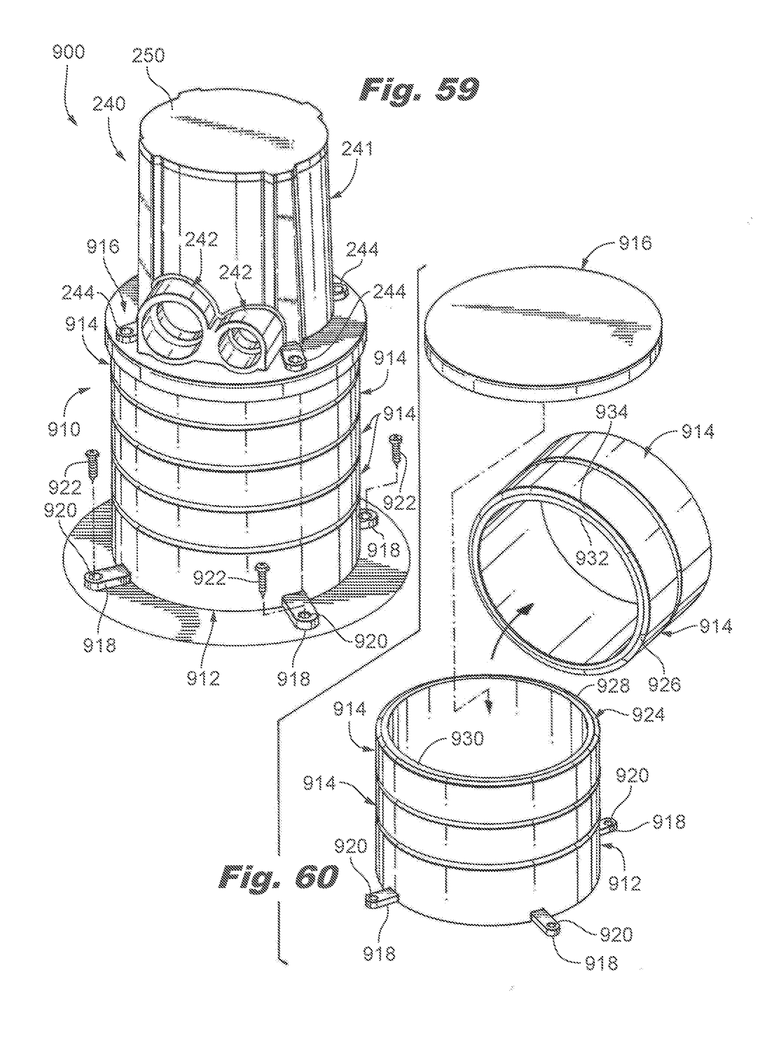

Referring now to FIGS. 59 and 60, another exemplary embodiment of a box assembly according to the present disclosure is shown. In this embodiment, the box assembly 900 includes a box 240 and a box-stand 910. The box 240 is the same as the box described above and for ease of description is not repeated. The box-stand 910 includes a series of concentric rings coupled or stacked together and then covered. For example, the box-stand 910 includes a base ring 912 and one or more intermediary rings 914 that can be stacked one upon the other to provide the desired height setting for the box 240. A cover 916 covers the rings 912 and 914 and provides a platform on which the box mat rest. The rings 912 and 914 and the cover 916 may be made of a non-metallic material, such as injection molded thermoplastic, or the rings may be made of a metallic material, such as galvanized steel, stainless steel or aluminum.

Referring to FIG. 60, the base ring 912 has one or more mounting tabs 918 extending from a side wall of the base ring. Each mounting tab 918 has a mounting aperture 920 through which a fastener 922, such as a screw, nail or spike can be passed to secure the base ring 912 and thus the box-stand 910 to sub-flooring, decking or grade. To stack the rings 912 and 914, the rings may be coupled using various types of quick fit structures. For example, the base ring 912 and the intermediate rings 914 may have a top portion 924 that can interlock with a bottom portion 926 of an intermediate ring 914. More specifically, in an exemplary embodiment, the top portion 924 may have a raised outer lip 928 and an inner edge 930, and the bottom portion 926 of the intermediate ring 914 has a raised inner lip 932 and an outer edge 934. When the rings 912 and 914 are stacked, the raised outer lip 928 of the top portion 929 rests against the outer edge 934 of the bottom portion 926, and the raised inner lip 932 of the bottom portion 926 rests against the inner edge 930 of the top portion 924. The base ring 912 or the base ring 912 and one or more intermediate rings 914 define the height setting for the box-stand 910. Once the desired height setting is reached, the top portion of the last intermediate ring 914 is covered by cover 916 which provides a platform upon which the box 240 may rest. The cover 916 may be secured to intermediate ring 914 using an adhesive, such as a PVC glue. The box 240 may be secured to the cover 916 using an adhesive, such as a PVC glue, double sided tape, a hook and loop type fastener, mechanical fasteners, such as sheet metal screws, or other type of fasteners.

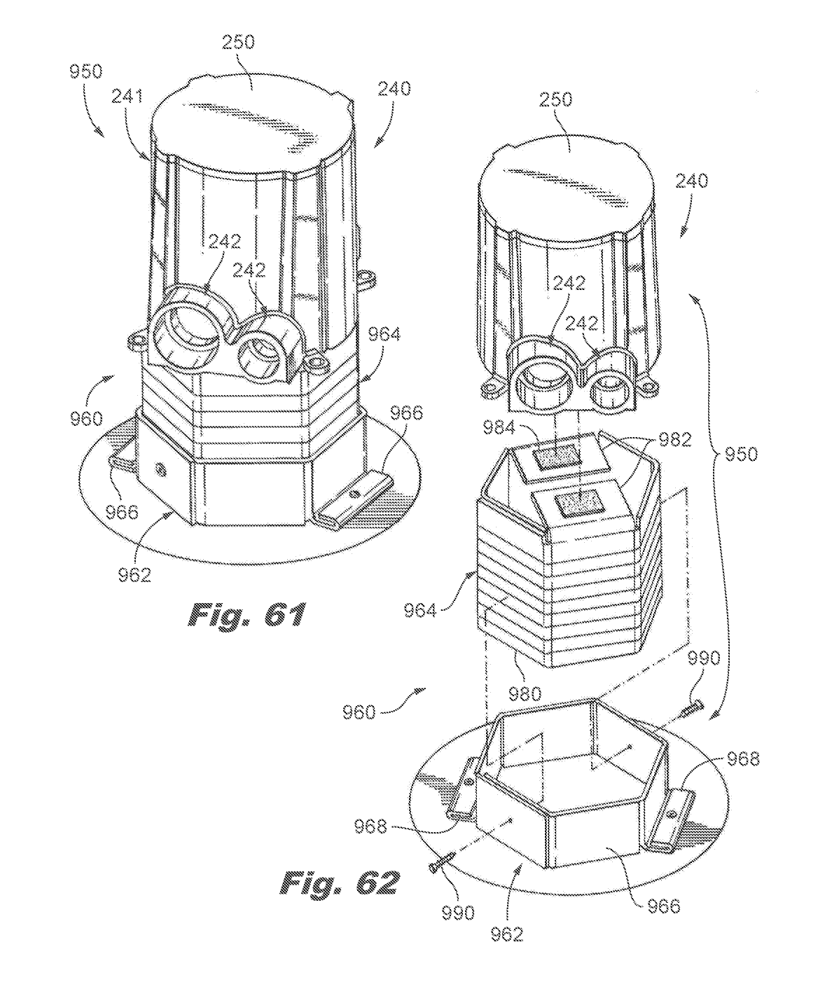

Turning now to FIGS. 61-64, another exemplary embodiment of a box assembly according to the present disclosure is shown. In this embodiment, the box assembly 950 includes a box 240 and a box-stand 960. The box 240 is described above and for ease of description is not repeated. The box-stand 960 includes a base ring 962 and height adjusting ring 964. The base ring 962 and height setting ring 964 are formed of a substrate that is foldable and capable of supporting a box and maintaining the height setting of the box until the poured concrete cures. Examples of a suitable substrate include cardboard, pliable plastic or rubber. The base ring 962 and height setting ring 964 may be folded into different shapes. For example, the rings may be square, rectangular, circular, polygon in shape, or any other shape. In the embodiment shown, the base ring 962 and height setting ring 964 have a hexagon shape, as shown in FIG. 62. The base ring 962 includes a side wall 966 and one or more anchor tabs 968 used to secure the base ring to a sub-floor, deck or grade. The side wall 966 has apertures 970 and 972 that are used to secure the height setting ring 964 to the base. Apertures 970 are also used to secure the ends of the side wall 966 together when the hexagon shape is formed. Each anchor tab 968 includes apertures 974 and 976 that are used when securing the base ring 962 to a sub-floor, deck or grade.

The height setting ring 964 includes a side wall 980 and one or more box supporting ledges 982 extending into a center portion of the height setting ring 964. The box supporting ledges 982 are provided to support a box 240. The box 240 may be secured to the box supporting ledges 982 using a fastener 984, seen in FIG. 62. The fastener may be an adhesive, such as a PVC glue, double sided tape, a hook and loop type fastener, a mechanical fastener or other types of known fasteners. In the embodiment shown, double sided tape is used as the fastener.

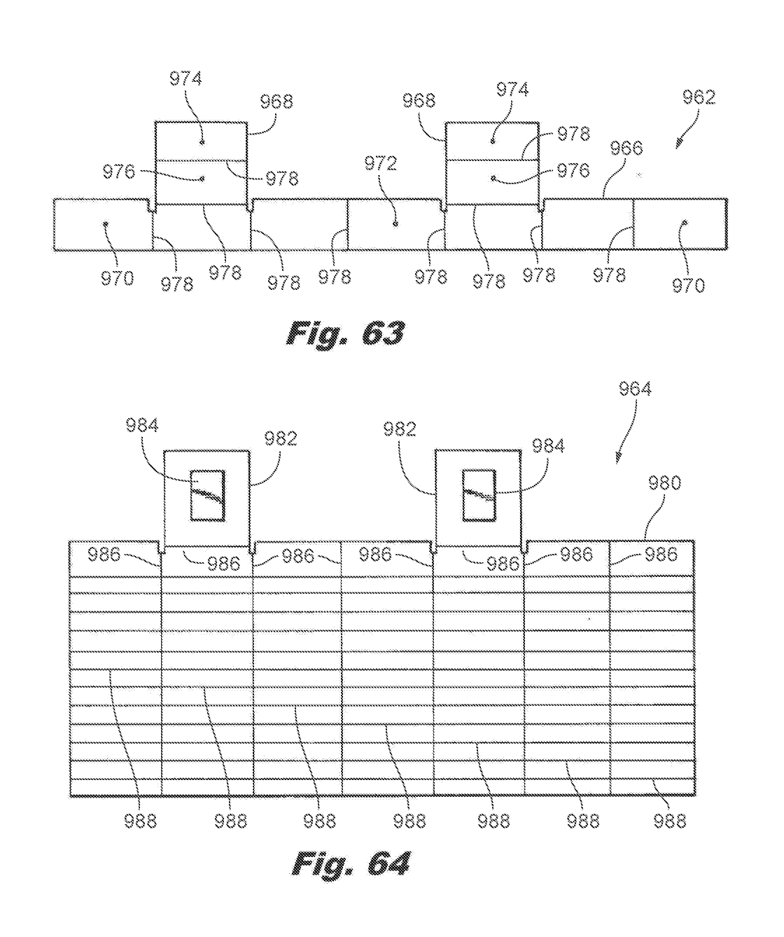

To fold the base ring 962 into a hexagon shape using a carboard substrate, the substrate is cut into a pattern of rectangular boxes with scored lines 978 that facilitate folding, as shown in FIG. 63. The substrate is then folded along the scored lines 978 into the base ring 962 shown in FIG. 62. To fold the height setting ring 964 into a hexagon shape using a carboard substrate, the substrate is cut into a pattern of rectangular boxes with vertical scored lines 986 that facilitate folding, as shown in FIG. 64. The substrate is then folded along the scored lines 986 into the height setting ring 964 shown in FIG. 62. To set the height of the box, the height setting ring 964 is cut along one of the horizontal score lines 988. The height setting ring 964 is then inserted into the base ring 962, as shown in FIG. 62, and the base ring is secured to the height setting ring using screws 990 through apertures 970 and 972 in the base ring.

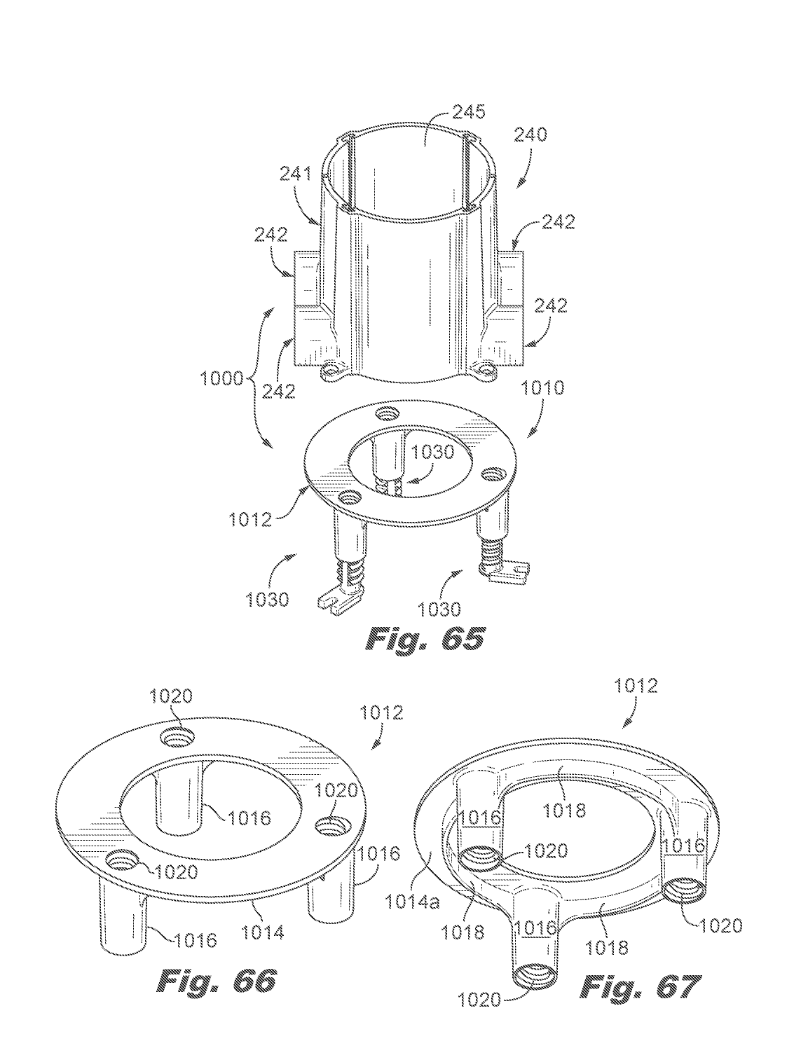

Turing to FIGS. 65-72, another exemplary embodiment of a box assembly according to the present disclosure is shown. In this embodiment, the box assembly 1000 includes a box 240 and a box-stand 1010. The box 240 is described above and for ease of description is not repeated. In this exemplary embodiment, the box-stand 1010 includes a base 1012 and one or more legs 1030. As shown in FIGS. 66 and 67, the base 1012 has a body 1014 and one or more leg support members 1016 extending from the body 1014. The leg support members 1016 may be secured to or integrally formed into the body 1014. In the embodiment shown, there are three leg support members 1016 integrally formed into the body 1014. To provide additional structural integrity to the leg support members 1016, braces 1018 may be secured to or integrally molded into the body 1014 and leg support members 1016, as shown in FIG. 67. As seen in FIGS. 66 and 67, each leg support member 1016 has a hollow threaded opening 1020 for coupling the leg support member to a leg 1030.

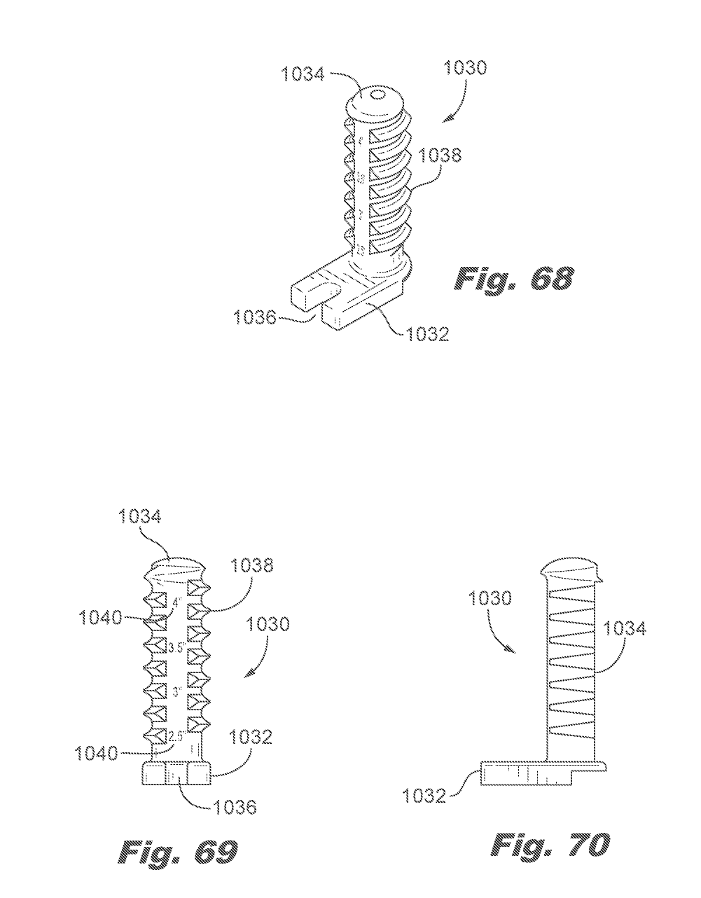

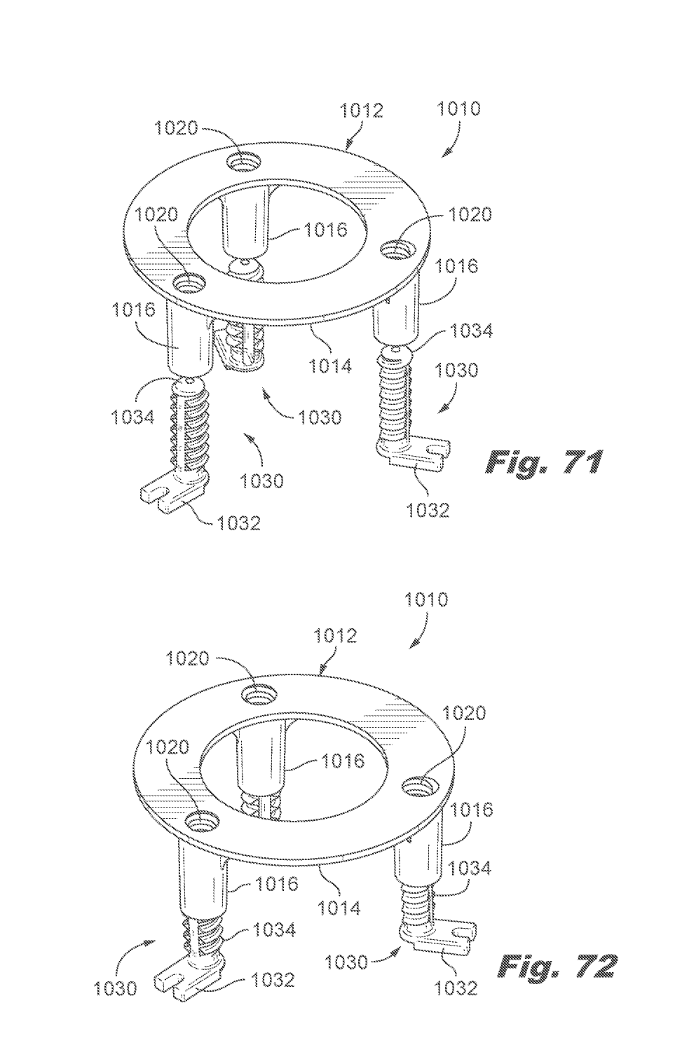

Referring to FIGS. 68-70, each leg 1030 includes a base 1032 and a stem 1034. The base 1032 includes a notch, slot or aperture 1036 that can be used to secure the leg 1030 to a sub-floor, grade or deck. Each stem 1034 is threaded with a thread 1038 that is configured to mate with the threaded opening 1020 in a leg support member 1016, as shown in FIGS. 71 and 72. Being able to separately adjust the legs 1030 relative to the base 1012, the different height settings for the legs 1030 permit adjustment to inconsistencies in the sub-flooring, decking or grade. For example, if a sub-floor, deck or grade were uneven, each leg 1030 may be set to different height settings to adjust to the uneven sub-floor, deck or grade. The stem 1034 may also include a plurality of markings, nomenclature or indicia 1040 positioned along the stem as shown in FIG. 69. The plurality of markings, nomenclature or indicia 1040 may be used to provide a general reference for leveling the box 240 and/or for setting a height of the box-stand 1010. For example, if the base 1032 of each leg 1030 is set to the 3 inch mark the box 240 will likely be level if the sub-floor, deck or grade is level. In another embodiment, the plurality of markings or indicia 1040 may reflect a predefined distance between the marking 1040 and the base 1032 of the leg 1030. For example, the 2.5 inch marking 1040 may represent a predefined distance between the body 1014 of base 1012 and the bottom of the base 1032, and the subsequent markings 1040 could be set at ½ inch intervals.

The box-stand 1010 may be made of a non-metallic material, such as injection molded thermoplastic, or the box-stand 1010 may be made of a metallic material, such as galvanized steel, stainless steel or aluminum. In another embodiment, the base 1012 may be made of a non-metallic material and the one or more legs 1030 may be made of a metallic material. In another embodiment, the base 1012 may be made of a metallic material and the one or more legs 1030 may be made of a non-metallic material.

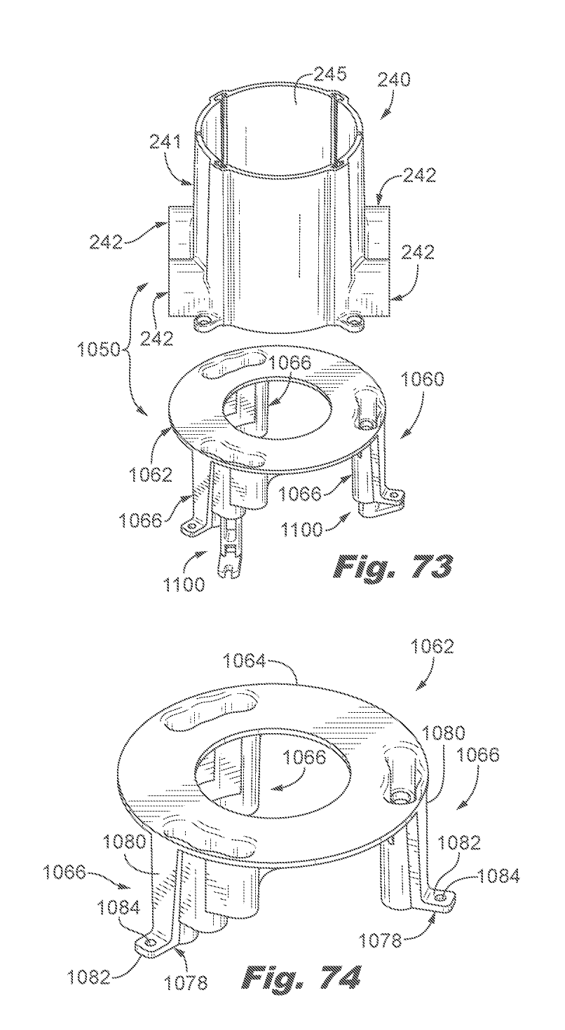

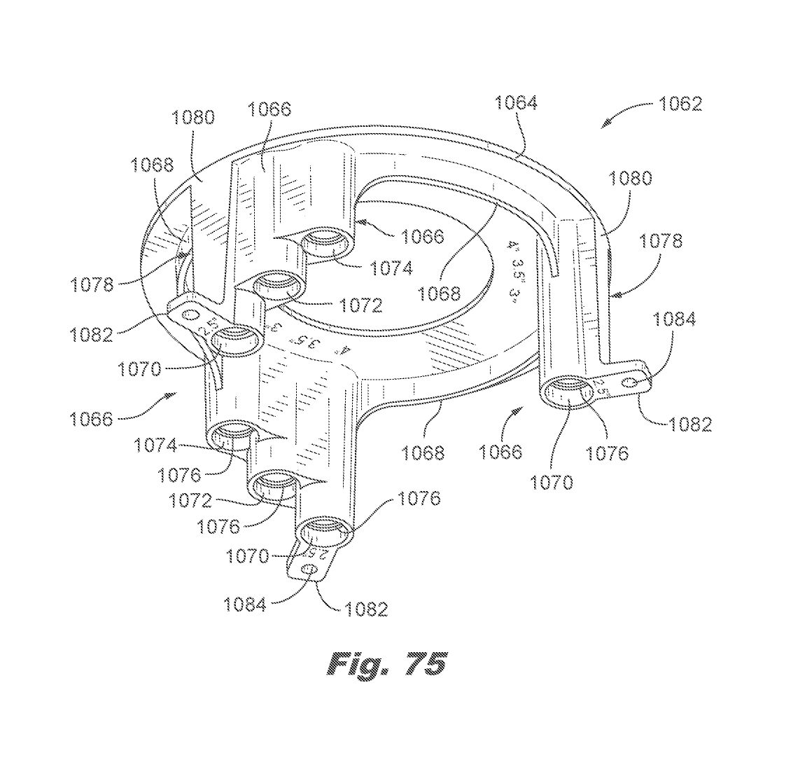

Turning to FIGS. 73-81, another exemplary embodiment of a box assembly according to the present disclosure is shown. In this exemplary embodiment, the box assembly 1050 includes a box 240 and a box-stand 1060. The box 240 is described above and for ease of description is not repeated. The box-stand 1060 includes a base 1062 and one or more legs 1100. As shown in FIGS. 74 and 75, the base 1062 has a body 1064 and one or more leg support members 1066 extending from the body 1064. The leg support members 1066 may be secured to or integrally formed into the body 1064. In the embodiment shown, there are three leg support members 1066 integrally formed into the body 1064, but any number of leg support members may be used. To provide additional structural integrity to the leg support members 1066, braces 1068 may be secured to or integrally molded into the body 1064 and leg support members 1066, as shown in FIG. 75.

As seen in FIGS. 74 and 75, each leg support member 1066 includes a plurality of offset hollow openings 1070, 1072 and 1074 used for coupling a leg 1100 to a leg support member. Each hollow opening 1070, 1072 and 1074 represents a different height setting for the legs 1100 and thus the box-stand 1060. For example, opening 1070 represents a 4-inch height setting for the legs 1100 and the box-stand 1060, whereas opening 1072 represents a 3.5-inch height setting for the legs 1100 and the box-stand 1060, whereas opening 1074 represents a 3-inch height setting for the legs 1100 and the box-stand 1060. In the embodiment shown, there are three hollow openings. However, less than three or more than three hollow openings may be formed into each leg support member 1066. Each hollow opening has a locking ring 1076 used to lock a leg 1090 to the leg support member 1066 at the height setting associated with the opening, as described below. Each leg support member 1066 may also include a height setting leg 1078 having a stem 1080 and a base 1082. Each height setting leg may be integrally formed into the leg support members 1066 as shown. In another embodiment, each height setting leg 1078 may be integrally formed into the body 1064 and separate from the leg support members 1066. The height setting legs 1078 may be used as a different height setting for the box-stand 1060. For example, as shown in FIG. 75, the height setting legs 1078 define a 2.5-inch height setting for the box-stand. The base 1082 of each height setting leg 1078 includes an aperture, notch or slot 1084 that can be used to secure the box-stand 1060 to a sub-floor, deck or grade.

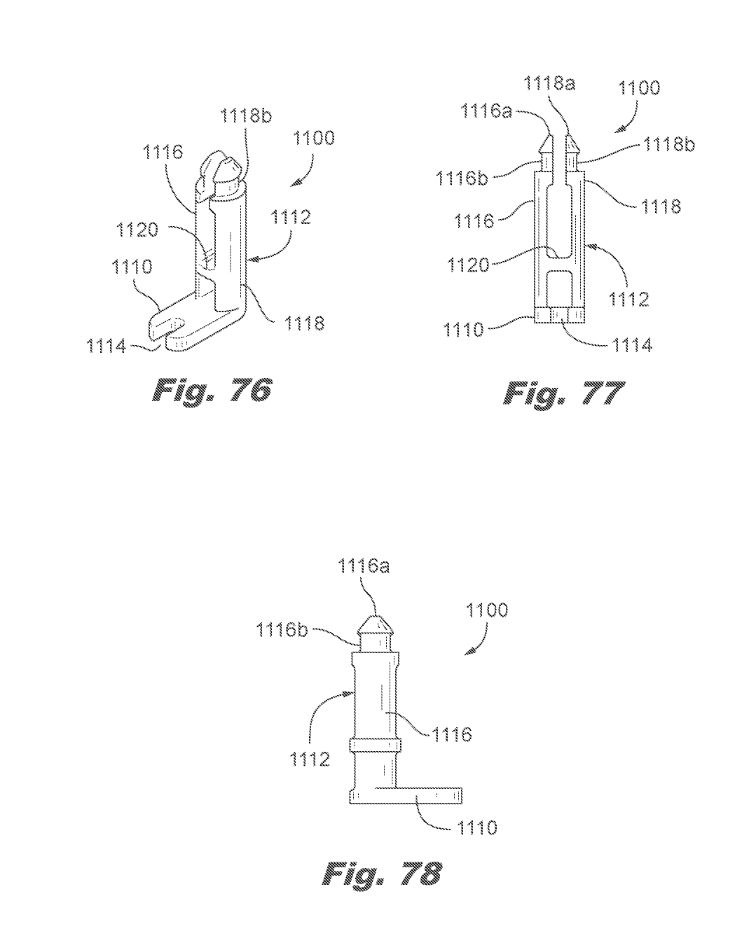

Referring to FIGS. 76-78, each leg 1100 includes a base 1110 and a stem 1112. The base 1110 includes a notch, slot or aperture 1114 that can be used to secure the leg 1100 to a sub-floor, grade or deck. Each stem 1112 is a split stem having a first stem portion 1116 and a second stem portion 1118. One end of each stem portion 1116 and 1118 is secured to or integrally molded into the base 1110, and the other end of each stem portion is a free end. At a point between the base 1110 and the free end of each stem portion 1116 and 1118 is a brace 1120 that interconnects the stem portions 1116 and 1118 together. In this configuration, the free ends of the stem portions 1116 and 1118 can flex relative to each other to facilitate locking the leg 1100 to the leg support member 1066. The free end of stem portion 1116 has a tapered tip 1116a forming a hook like structure and a channel 1116b, and the free end of stem portion 1118 has a tapered tip 1118a forming a hook like structure and a channel 1118b. The hooks and channels interact with a locking ring 1076 within a hollow opening 1070, 1072 or 1074 in a leg support member 1066 to lock a leg 1100 to the leg support member.

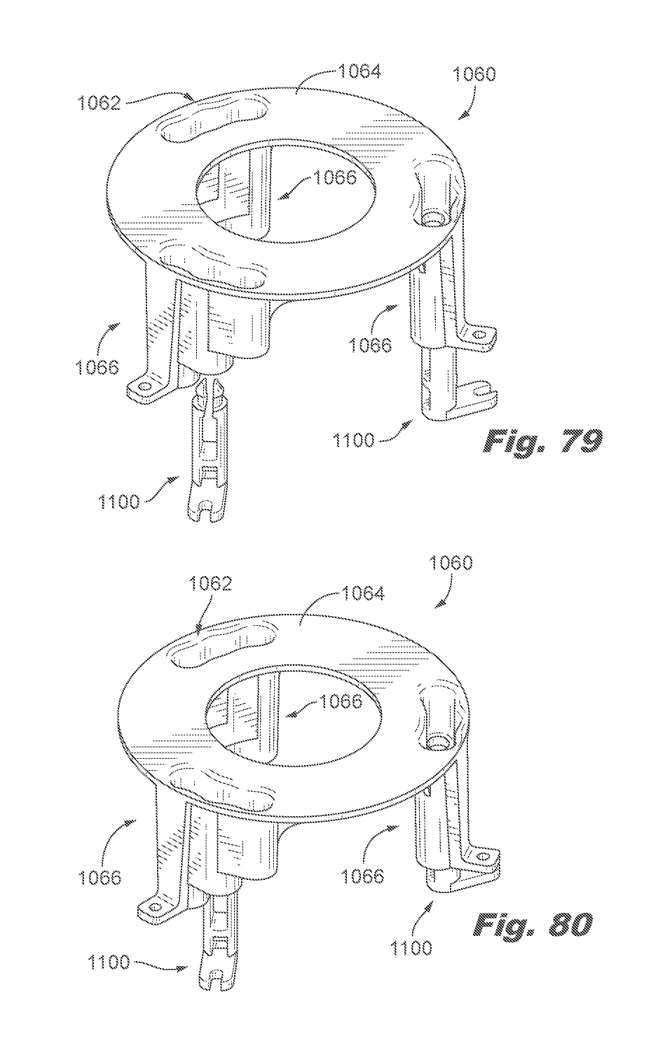

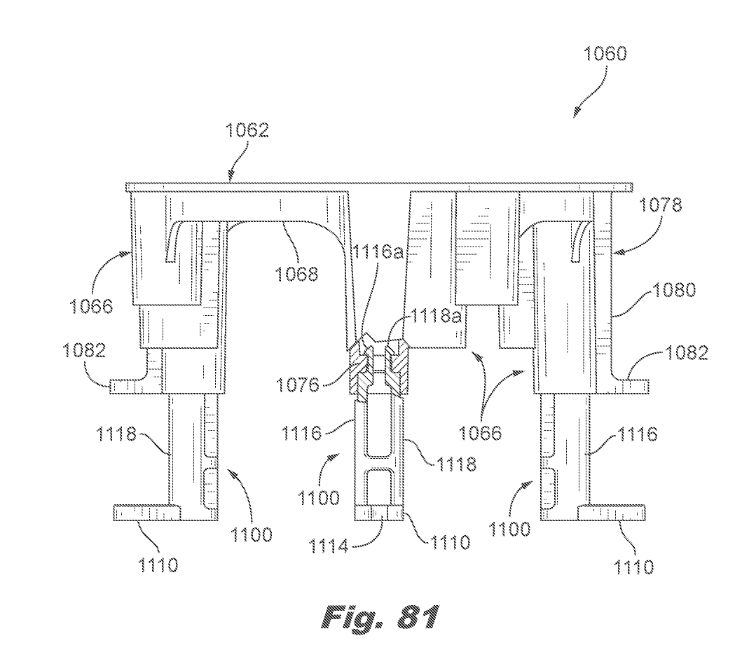

Referring to FIGS. 79-81, attaching a leg 1100 to the base 1062 will be described. If the height setting legs 1078 are to be used as the desired height of the box-stand 1060 then the legs 1100 are not needed and the height setting leg is secured to the sub-floor, deck or grade via base 1110. If the height setting legs 1078 are not to be used as the desired height of the box-stand 1060 then the legs 1100 are needed. Initially, a leg 1100 is positioned relative to the desired hollow opening 1070, 1072 or 1074 for each leg support member 1066. The stem 1112 of each leg 1100 is inserted into the desired hollow opening until the tapered tips 1116a and 1118a of each stem portion 1116 and 1118, respectively, engage the locking ring 1076 within the hollow opening 1070, 1072 or 1074. Additional force is then applied to the leg 1100 such that the camming surface of the tapered tips 1116a and 1118a slide against the locking ring 1076 causing the free ends of each stem portion 1116 and 1118 to flex toward each other allowing the free ends of the stem portions 1116 and 1118 to move past the locking ring 1076. When the camming surface of the tapered tips 1116a and 1118a passes the locking ring 1076, the channels 1116b and 1118b of each stem portion 1116 and 1118, respectively, remove the force applied to the stem portions allowing the free ends of the stem portions to return to their natural, unbiased position such that the hooks of the tapered tips 1116a and 1118a prevent the leg 1110 from being removed from the leg support member 1066, as shown in FIG. 81.

The box-stand 1060 may be made of a non-metallic material, such as injection molded thermoplastic, or the box-stand 1060 may be made of a metallic material, such as galvanized steel, stainless steel or aluminum. In another embodiment, the base 1062 may be made of a non-metallic material and the one or more legs 1100 may be made of a metallic material. In another embodiment, the base 1062 may be made of a metallic material and the one or more legs 1100 may be made of a non-metallic material.

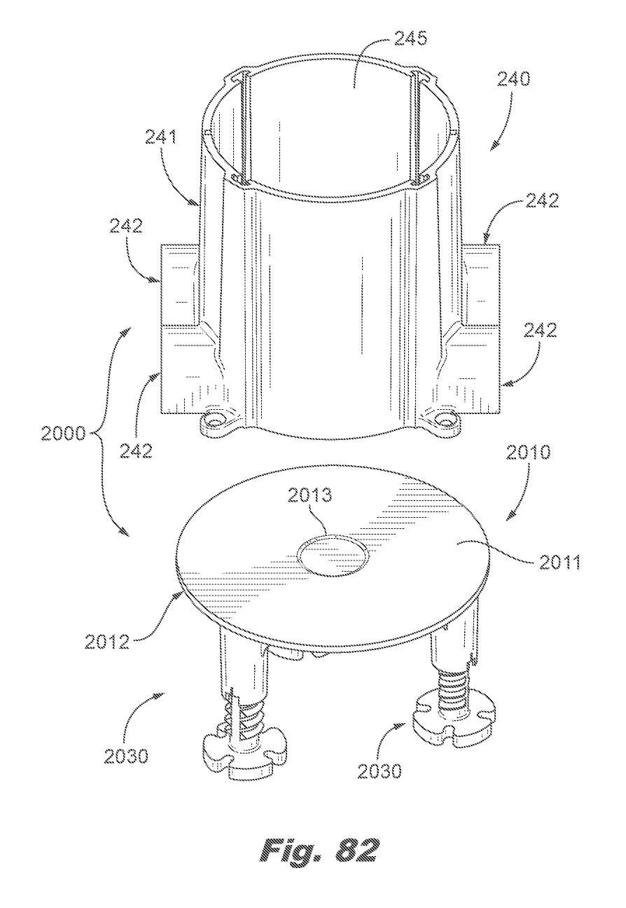

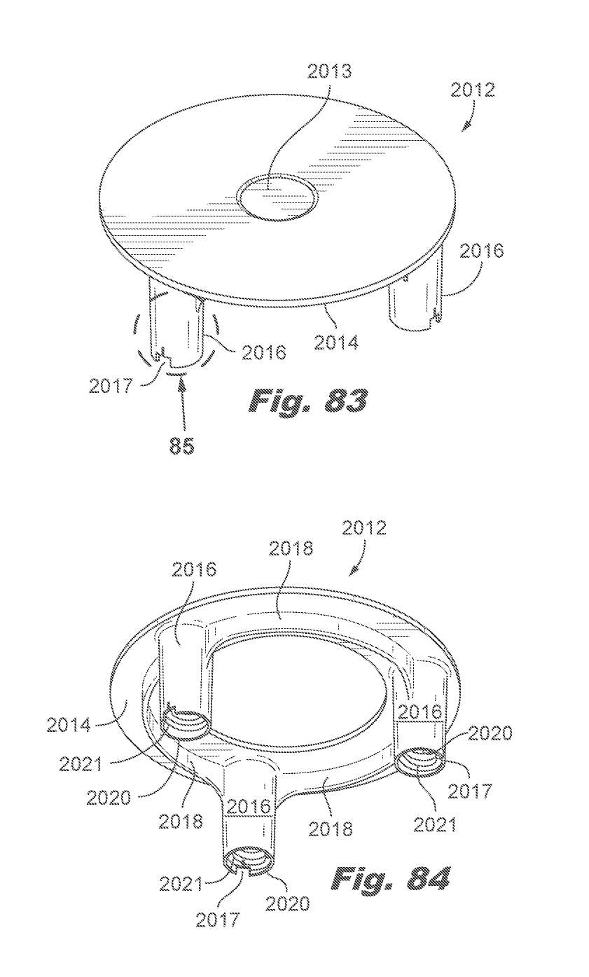

Turning to FIGS. 82-90, another exemplary embodiment of a box assembly according to the present disclosure is shown. In this embodiment, the box assembly 2000 includes a box 240 and a box-stand 2010. The box 240 is described above and for ease of description is not repeated. In this exemplary embodiment, the box-stand 2010 includes a base 2012 and one or more legs 2030. As shown in FIGS. 83 and 84, the base 2012 has a body 2014 and one or more leg support members 2016 extending from the body 2014. The leg support members 2016 may be secured to or integrally formed into the body 2014. In the embodiment shown, there are three leg support members 2016 integrally formed into the body 2014. To provide additional structural integrity to the leg support members 2016, braces 2018 may be secured to or integrally molded into the body 2014 and leg support members 2016, as shown in FIG. 84. Each leg support member 2016 has a hollow cavity 2020 along its central axis for coupling the leg support member to a leg stem 2034. According to one embodiment, the inside surface of the cavity includes a threaded surface 2021 to engage a corresponding threaded surface of a leg stem 2034, seen in FIG. 86.

The top of the box-stand 2010 is a continuous surface 2011. Positioned in the surface 2011 is a reservoir 2013 formed as, for example, a depression. According to one embodiment, the box 240 is connected to the box-stand 2010 by placing an adhesive on the surface 2011 and pressing the lower surface of the box 240 against the top of the box-stand 2010. The reservoir 2013 may serve to hold additional adhesive to enhance adhesion of the box 240 to the box-stand 2010. In addition, surface 2011 may be textured or be comprised of a material to facilitate adhesion of the box 240 and box stand 2010.

Referring to FIGS. 86-88, each leg 2030 includes a base 2032 and a stem 2034. The base 2032 includes a plurality of notches, slots or apertures 2036 that can be used to secure the leg 2030 to a sub-floor, grade or deck. According to one embodiment, the notches, slots, or apertures 2036 are arranged radially around the base 2032 and at an equal distance from the axis of the stem 2034.

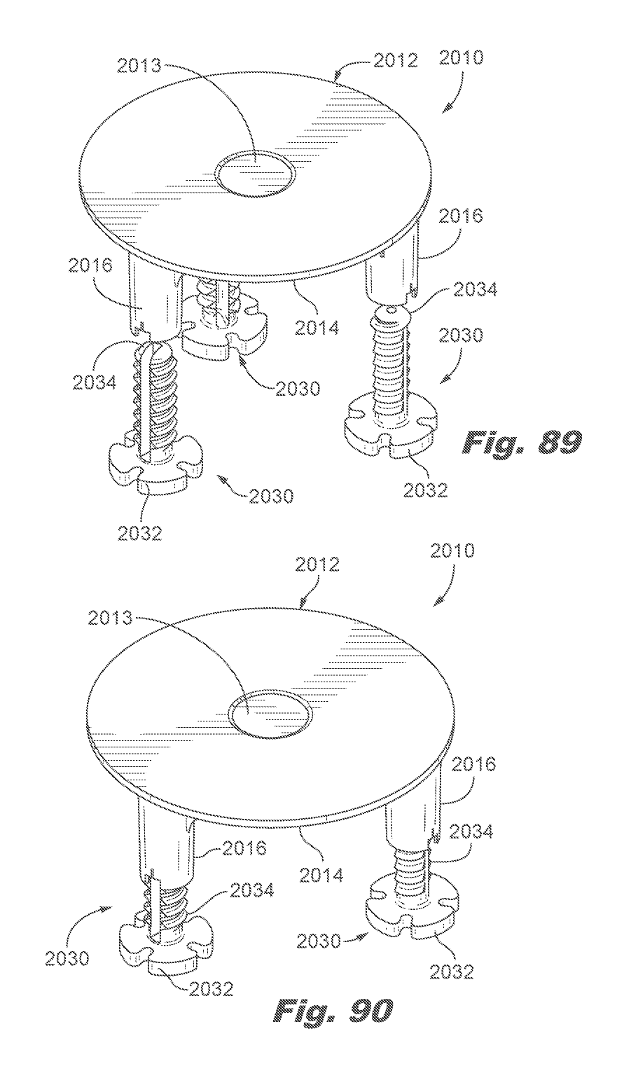

Each stem 2034 is threaded with a thread 2038 that is configured to correspond to and mate with the threaded surface 2021 within the apertures 2020 in a leg support member 2016, as shown in FIGS. 89 and 90. Rotation of the legs 2030 relative to the leg supports 2016 causes the legs to thread into or out of the legs support so that the box-stand 2010 can be adjusted to support the box 240 at a desired height relative to a sub-floor, deck or grade. Notches 2036 in the base 2032 of a leg 2030 allow the base to be fixed to the sub-floor, for example, by positioning screws, nails, or bolts in the sub-floor within one or more of the notches 2036. Once secured to the sub-floor, the leg stems 2034 are no longer able to rotate relative to the leg supports 2016 and the height of the box-stand 2010 at the point where each leg stem 2034 is engaged with its respective the leg support 2016 is fixed. According to one embodiment, four notches 2036 are provided on the base of each leg. For installations where notches 2036 engage fixtures already located on the sub-floor, for example, threaded rods cemented into the sub-floor, the four notches 2036 of this embodiment may allow the position of the leg to be fixed at 90 degree intervals for each rotation relative to the leg support 2030. For installations where a screw, nail or other fastener will affix legs 2030 to the sub-floor after the box stand 2010 is positioned in place, providing multiple notches 2036 may allow an installer to more easily access one or more notches facing outward from the box-stand 2010 when the engagement between the leg 2034 and leg support 2016 is at the desired length.

Each leg 2030 can be adjusted independent of the others. Being able to separately adjust the legs 2030 relative to the base 2012, the different height settings for the legs 2030 permit adjustment to inconsistencies in the sub-flooring, decking or grade. For example, if a sub-floor, deck or grade were uneven, each leg 2030 may be set to different height settings to adjust to the uneven sub-floor, deck or grade.

The leg stem 2034 may also include a plurality of markings, nomenclature or indicia 2040 positioned along the stem as shown in FIG. 87. The plurality of markings, nomenclature or indicia 2040 may be used to provide a general reference for leveling the box 240 and/or for setting a height of the box-stand 2010. For example, if the engagement of the stem 2034 of each leg 2030 with its respective leg support 2016 is set to the 3 inch mark, the box 240 will likely be level if the sub-floor, deck or grade is level. In another embodiment, the plurality of markings or indicia 2040 may reflect a predefined distance between the marking 2040 and the base 2032 of the leg 2030. For example, the 2.5 inch marking 2040 may represent a predefined distance between the body 2014 of base 2012 and the bottom of the base 2032, and the subsequent markings 2040 could be set at ½ inch intervals.

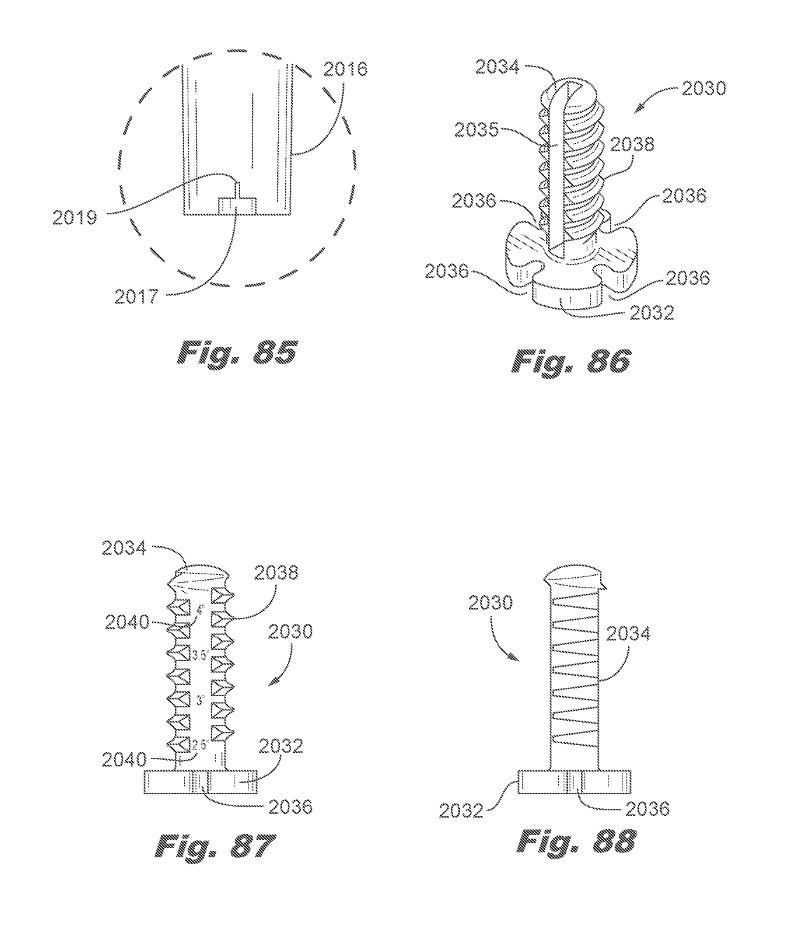

As shown in FIG. 85, leg supports 2030 include a slot 2017 through the outward facing surface of the leg support 2030. The slot 2017 is shaped to allow a user to view the marking or indicia 2040 closest to the leg support 2016 when the leg stem 2034 is positioned within the leg support 2016. For example, if the markings 2040 show distances such as 2.5″, 3″, 3.5″, etc. as shown in FIG. 87, the slot 2017 may be shaped so that it brackets the numerical indicia corresponding to the selected height. The slots 2017 may be shaped to indicate a center line of the slot by including a smaller notch or indicia 2019. According to one embodiment, rotating the stem 2034 relative to the support 2016 so that notch 2019 aligns with a center of marking 2040 indicates that the distance indicated by the marking 2040 is accurate.

As shown in FIG. 86, leg stem 2034 includes a hollow portion 2035 open along the axis of the leg and extending along interior of the leg. Providing a hollow portion of the leg stem 2034 may allow the thickness of the leg to be selected to provide adequate strength to support the box 240, while reducing the amount of material required to form the leg 2030. In addition, hollow portion 2035 may reduce the maximum thickness of material forming the leg 2030, potentially simplifying molding the leg, for example, by injection molding. According to one embodiment, the hollow section 2035 is positioned opposite from markings 2040 across the axis of the stem 2034. Threads 2038 extend around the stem 2034 and are interrupted where they encounter the markings 2040 and hollow portion 2035.

The box-stand 2010 may be made of a non-metallic material, such as injection molded thermoplastic, or the box-stand 2010 may be made of a metallic material, such as galvanized steel, stainless steel or aluminum. In another embodiment, the base 2012 may be made of a non-metallic material and the one or more legs 2030 may be made of a metallic material. In another embodiment, the base 2012 may be made of a metallic material and the one or more legs 2030 may be made of a non-metallic material.

While illustrative embodiments of the present disclosure have been described and illustrated above, it should be understood that these embodiments are exemplary and are not to be considered as limiting. Additions, deletions, substitutions, and other modifications can be made without departing from the spirit or scope of the present disclosure. Accordingly, the present disclosure is not to be considered as limited by the foregoing description.

What is claimed is:

1. An adjustable box-stand comprising:
a base having a body and at least one leg support members extending from the body; and
at least one leg having a leg base and a stem;
wherein the stem of the at least one leg is adjustable relative to the at least one leg support member.

2. The adjustable box-stand according to claim 1, wherein the support member comprises a threaded surface, wherein the stem comprises a corresponding threaded surface, wherein the corresponding threaded surface is configured to engage the threaded surface of the support member, and wherein the stem is adjustable relative to the support member by engaging selected portions of the threaded and corresponding threaded surfaces.

3. The adjustable box-stand according to claim 2, wherein the at least one leg support member has an aperture, the threaded surface disposed within the aperture, wherein the stem of the at least one leg comprises the corresponding threaded surface on its outer surface, and wherein the stem of the at least one leg is adjusted relative to the at least one leg support member by threading the stem into or out of the threaded aperture.

4. The adjustable box-stand according to claim 1, wherein the stem of the at least one leg comprises a plurality of markings used to set a height of the body.

5. The adjustable box-stand according to claim 4, wherein the leg support member further comprises a notch, wherein when the stem is engaged with the leg support the notch is positioned adjacent a selected one of the markings.

6. The adjustable box-stand according to claim 1, wherein the leg base has at least one aperture or slot that can be used to anchor the at least one leg to a subfloor, deck or grade.

7. The adjustable box-stand according to claim 1, wherein the at least one leg support member is integrally molded into or secured to the body.

8. The adjustable box-stand according to claim 1, wherein the at least one leg support member comprises a plurality of leg support members integrally molded into or secured to the body.

9. The adjustable box-stand according to claim 1, wherein the at least one leg support member comprises a plurality of leg support members secured to the body.

10. The adjustable box-stand according to claim 1, wherein the body comprises a continuous bonding surface and an adhesive reservoir, and wherein the adhesive reservoir is set into the continuous surface.

11. The adjustable box-stand according to claim 1, wherein the base further comprises a plurality of apertures arranged radially around the stem.

12. The adjustable box-stand according to claim 11, wherein the plurality of apertures comprise four apertures arranged radially symmetrically about the stem.

13. The adjustable box-stand according to claim 1, wherein the stem comprises a hollow section along an axis of the stem.

14. An adjustable box assembly comprising:
an electrical box; and
an adjustable box-stand for supporting the electrical box, the adjustable box-stand comprising:
a base having a body and at least one leg support members extending from the body; and
at least one leg having a leg base and a stem;
wherein the stem of the at least one leg is adjustable relative to the at least one leg support member.

15. The adjustable box assembly according to claim 14, wherein the support member comprises a threaded surface, wherein the stem comprises a corresponding threaded surface, wherein the corresponding threaded surface is configured to engage the threaded surface of the support member, and wherein the stem is adjustable relative to the support member by engaging selected portions of the threaded and corresponding threaded surfaces.

16. The adjustable box assembly according to claim 15, wherein the at least one leg support member has an aperture, the threaded surface disposed within the aperture, wherein the stem of the at least one leg comprises the corresponding threaded surface on its outer surface, and wherein the stem of the at least one leg is adjusted relative to the at least one leg support member by threading the stem into or out of the threaded aperture.

17. The adjustable box assembly according to claim 14, wherein the stem of the at least one leg comprises a plurality of markings used to set a height of the body.

18. The adjustable box assembly according to claim 17, wherein the leg support member further comprises a notch, wherein, when the stem is engaged with the leg support the notch is positioned adjacent a selected one of the markings.

19. The adjustable box assembly according to claim 14, wherein the base further comprises a plurality of apertures arranged radially around the stem.
